(19) United States
(12) Patent Application Publication
(10) Pub. No.: US 2024/0096701 A1
(43) Pub. Date: Mar. 21, 2024

(54) DEVICE WITH THROUGH VIA AND RELATED METHODS

(71) Applicant: Taiwan Semiconductor Manufacturing Co., Ltd., Hsinchu (TW)

(72) Inventors: Chun-Yuan CHEN, Hsinchu (TW); Huan-Chieh SU, Hsinchu (TW); Ching-Wei TSAI, Hsinchu (TW); Shang-Wen CHANG, Hsinchu (TW); Yi-Hsun CHIU, Hsinchu (TW); Chih-Hao WANG, Hsinchu (TW)

(21) Appl. No.: 18/172,240

(22) Filed: May 17, 2023

Related U.S. Application Data
(60) Provisional application No. 63/408,437, filed on Sep. 20, 2022.

(51) Int. Cl. H01L 21/768; H01L 23/48; H01L 29/40; H01L 29/417; H01L 29/66

(52) U.S. Cl. CPC H01L 21/76898; H01L 23/481; H01L 29/401; H01L 29/41733; H01L 29/66439; H01L 29/66742; H01L 29/775

(57) ABSTRACT

A device includes: a stack of semiconductor nanostructures; a gate structure wrapping around the semiconductor nanostructures, the gate structure extending in a first direction; a source/drain region abutting the gate structure and the stack in a second direction transverse the first direction; a contact structure on the source/drain region; a backside conductive trace under the stack, the backside conductive trace extending in the second direction; a first through via that extends vertically from the contact structure to a top surface of the backside dielectric layer; and a gate isolation structure that abuts the first through via in the second direction.

### PRIORITY CLAIM AND CROSS-REFERENCE

This application claims the benefit of priority to U.S. Provisional Application Ser. No. 63/408,437, entitled “SEMICONDUCTOR STRUCTURE AND METHOD FOR MANUFACTURING THE SAME,” filed on Sep. 20, 2022, which application is incorporated by reference herein in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrammatic perspective views of a portion of an IC device according to embodiments of the present disclosure.

FIGS. 2A-11 are views of an IC device at various stages of fabrication according to aspects of the present disclosure.

FIGS. 12-29 are views of various embodiments of an IC device at various stages of forming through vias in accordance with various embodiments.

FIGS. 30A-30F are diagrammatic perspective views of the IC device in accordance with various embodiments.

FIGS. 31A-31F are diagrammatic cross-sectional side views of the through vias in accordance with various embodiments.

FIG. 32 is a flowchart illustrating method of fabricating a semiconductor device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as planar FETs, three-dimensional fin-line FETs (FinFETs), or nanostructure devices. Examples of nanostructure devices include gate-all-around (GAA) devices, nanosheet FETs (NSFETs), nanowire FETs (NWFETs), and the like. In advanced technology nodes, with scaling down of integrated circuit (IC) devices, routing both signal wires and power wires (or rails) at the frontside of the substrate is increasingly challenging. When scaling down, space for interconnects decreases, increasing difficulty of power rail design. For example, power rails may be narrow to increase spacing for signal wires, which increases resistance and reduces power efficiency.

Embodiments disclosed herein provide power from the backside of the IC device, which improves frontside signal routing flexibility and allows wired power rail formation, which reduces resistance and increases power efficiency. Embodiments include through vias that enable backside power delivery and improve frontside signal routing spacing. In some embodiments, a power via (PV) and a signal via (SV) are designed to electrically connect source/drain contacts (or “MD”) to respective traces of a backside metal layer, such as a lowest backside metal layer (or “BM0”). Other backside interconnect features, such as conductive traces and vias, may be stacked on higher backside metal layers (e.g., BM1, BM2, BM3, BM4) to provide routing of power wires, signal wires, or both on the backside of the IC device.

Embodiments disclosed herein provide methods of fabrication of the power via. In some embodiments, the through vias are formed from the frontside by depositing conductive material of the through vias in an opening formed prior to forming the source/drain contacts. In some embodiments, the opening is formed from the backside, then the through vias are formed from the backside by depositing the conductive material in the opening. In some embodiments, a first opening is formed from the frontside, a dielectric plug is formed in the first opening, a second opening is formed from the backside by removing the dielectric plug, and the through vias are formed by depositing the conductive material in the second opening from the backside.

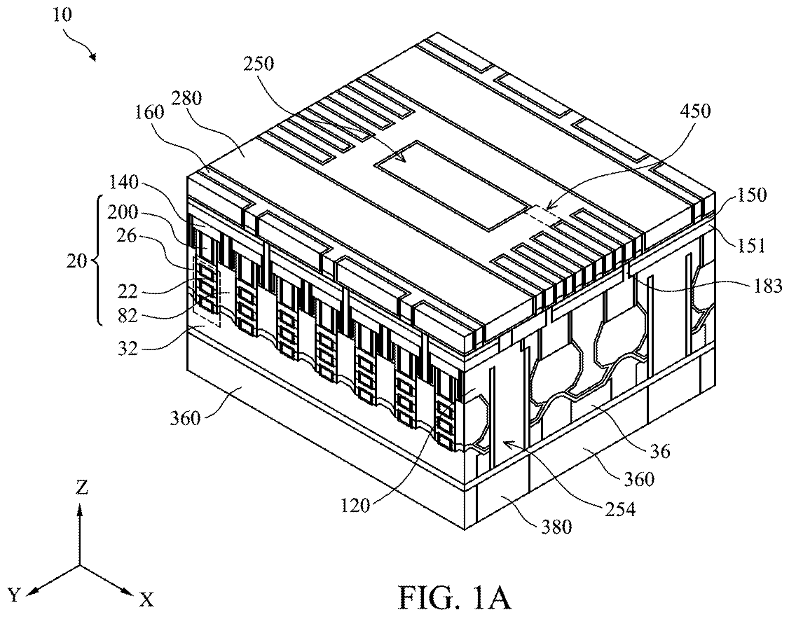

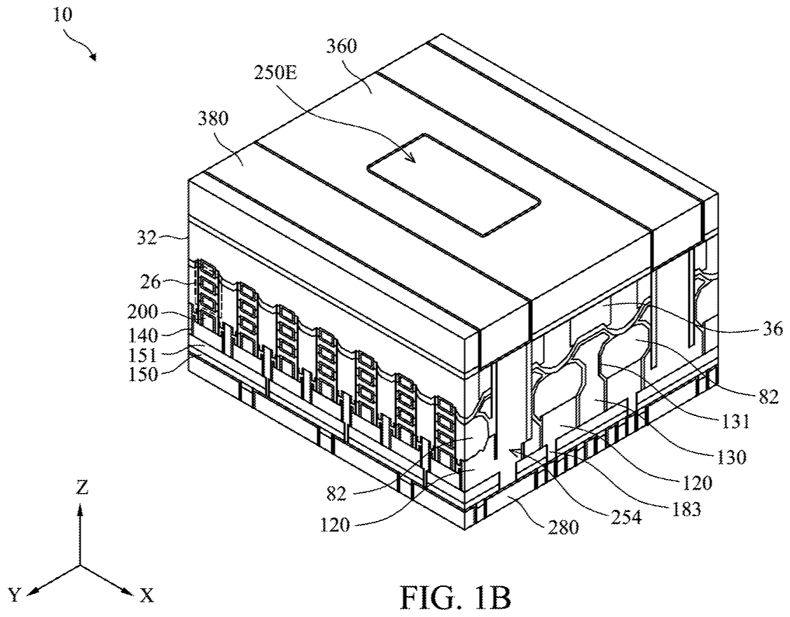

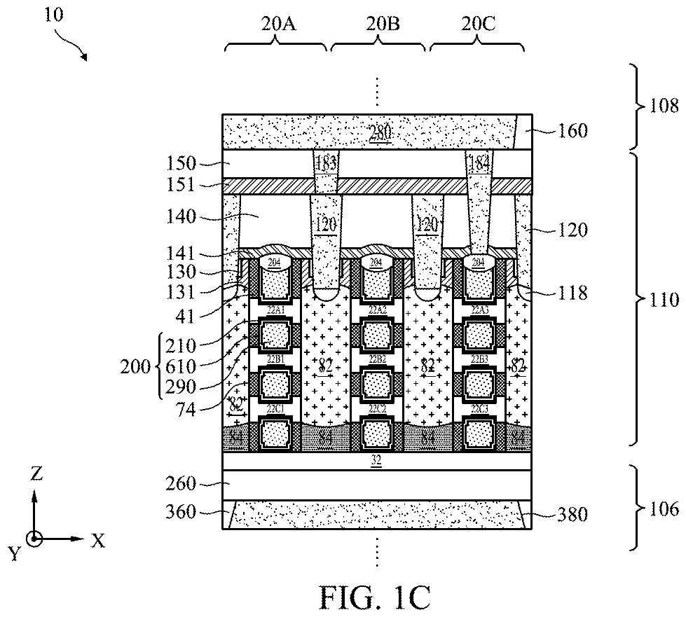

FIGS. 1A, 1B illustrate portions of IC device 10 in accordance with various embodiments. FIG. 1A is a diagrammatic perspective view of a portion of IC device 10 in frontside-up orientation in accordance with various embodiments. FIG. 1B is a diagrammatic perspective view of the portion of the IC device 10 in a backside-up orientation in accordance with various embodiments.

In FIG. 1A, nanostructure devices 20 are positioned at regions in which nanostructure channels 22 have gate structures 200 wrapped therearound, and are abutted on either side by source/drain regions 82. Source/drain region(s) may refer to a source or a drain, individually or collectively dependent upon the context. The nanostructure devices 20 may include n-type transistors, p-type transistors, or both. IC cells that include the nanostructure devices 20 may include other integrated devices, such as integrated capacitors, integrated resistors, integrated inductors, integrated diodes, or the like.

Through vias 250, 254 are positioned in the IC device 10. The through via 254 may be a power via 254, and may electrically connect one or more of the source/drain regions 82 at the frontside of the IC device 10 with a power line 380 at a backside of the IC device 10. For example, the source/drain region 82 may be in contact with a source/drain contact 120, which is in contact with the power via 254, which is in contact with the power line 380. Additional source/drain regions 82 may be coupled to the power via 254 by a frontside power line 280, as shown in FIG. 1A. Including both the power line 380 and the frontside power line 280 is advantageous to reduce electrical resistance, increase current and increase speed.

The through via 250 may be a signal via 250, and may electrically connect one or more of the source/drain regions 82 at the frontside of the IC device 10 with a signal pad or signal line 250E at a backside of the IC device 10. For example, a source/drain region 82 may be in contact with a source/drain contact 120, which is in contact with the signal via 250, which is in contact with the signal pad 250E. In some embodiments, the source/drain contact 120 may be in electrical contact with the signal via 250 by an optional connecting trace 450, illustrated in phantom in FIG. 1A. The connecting trace 450 may be disposed in the same metal layer that the frontside power line 280 is disposed in. The signal via 250 is advantageous in many respects, including greater area at the backside of the IC device 10 for transferring signals, elimination or reduction of complicated routing, and increased speed. The signal via 250 may be particularly advantageous for “wire-dominated cells,” which transfer signals over relatively longer distances. Instead of connecting upwardly on the frontside of the IC device 10, which involves complicated routing through many metal layers (e.g., 8 or more metal layers) by connecting to the signal via 250, routing complexity is reduced. Other cells, such as “gate-dominated cells,” may be routed on the frontside of the IC device 10, without connecting to the signal via 250, as signal paths included therein may be relatively short. The IC device 10 may include gate-dominated cells, wire-dominated cells, or a combination thereof.

In some embodiments, the through vias 250, 254 are or comprise one or more of W, Ru, Co, Cu, Mo, or the like. The through vias 250, 254 may include one or more glue layers, which may be TaN, TiN, or the like. In some embodiments, the glue layer is omitted, such that the metal material of the through vias 250, 254 is in direct contact with adjacent features thereof. The glue layer may be disposed on and along sidewalls of the metal material of the through vias 250, 254.

Height of the through vias 250, 254 (e.g., in the Z-axis direction) may be in a range of about 60 nm to about 180 nm, which may be selected by a chemical mechanical polishing (CMP) operation on the frontside and a wafer thinning operation on the backside.

Length of the power vias 254 (e.g., in the X-axis direction) may be a multiple of a minimum gate pitch (CPP) of the IC device 10. A multiple of a minimum gate pitch (CPP) may refer to a number of gate structures 200 passed through by the power via 254. The CPP may be, for example, 20 nanometers (nm), 16 nm, 10 nm, 7 nm, 5 nm, 3 nm, 2 nm, 1.4 nm, 1 nm or another suitable size. In some embodiments, the length of the power vias 254 is in a range of about 0.5 CPP to about 24 CPP. Width of the power vias 254 (e.g., in the Y-axis direction) may be in a range of about 10 nm to about 40 nm.

The signal via 250 is disposed within the IC cell, and is advantageous for providing a low-resistance signal path for transmitting signals from the frontside of the IC device 10 to the backside of the IC device 10. Length of the signal via 250 may be in a range of about 1 CPP to about 10 CPP. Width of the signal via 250 may be in a range of about 10 nm to about 150 nm.

FIG. 1C illustrates a diagrammatic cross-sectional side view of a portion of the IC device 10 fabricated according to embodiments of the present disclosure, where the IC device 10 includes nanostructure devices 20, such as nanostructure devices 20A, 20B, 20C. The nanostructure devices 20 may be n-type FETs (NFETs), p-type FETs (PFETs), or both, in some embodiments. Integrated circuit devices such as the IC device 10 frequently include transistors having different threshold voltages based on their function in the IC device. For example, input/output (IO) transistors typically have the highest threshold voltages due to the high current handling required of the IO transistors. Core logic transistors typically have the lowest threshold voltages to achieve higher switching speeds at lower operating power. A third threshold voltage between that of the IO transistors and that of the core logic transistors may also be employed for certain other functional transistors, such as static random access memory (SRAM) transistors. Some circuit blocks within the IC device 10, such as one or more of the IC cells 100A-100C, may include two or more NFETs and/or PFETs of two or more different threshold voltages.

The cross-sectional view of the IC device 10 in FIG. 1C is taken along an X-Z plane, where the X-direction is the horizontal direction, and the Z-direction is the vertical direction. The nanostructure device 20A is described in detail as an illustrative example. The nanostructure devices 20B, 20C may be similar or identical in all or most respects to the nanostructure device 20A.

The nanostructure device 20A includes channels 22A1, 22B1, 22C1 (alternately referred to as “nanostructures 22” or “channels 22”) over an optional fin structure 32. In some embodiments, the fin structure 32 is removed with a substrate 110 during backside processing (see FIGS. 36 and 37, for example).

The channels 22 are laterally abutted by source/drain regions 82, and covered and wrapped around (or “surrounded”) by gate structure 200. The gate structure 200 controls flow of electrical current through the channels 22 based on voltages applied at the gate structure 200 and at the source/drain regions 82. The threshold voltage is a voltage (e.g., gate-source voltage or source-gate voltage) below which negligible current flows through the channels 22, and above which significant current (e.g., orders of magnitude more current) flows through the channels 22. Voltage at or above the threshold voltage establishes a conducting path in the channels 22. Threshold voltage tuning may be performed during fabrication of the various transistors, e.g., IO transistors, core logic transistors, and SRAM transistors, for example, during fabrication of the gate structure 200.

In some embodiments, the fin structure 32 includes silicon. In some embodiments, the nanostructure device 20 is an NFET, and the source/drain regions 82 thereof include silicon phosphorous (SiP). In some embodiments, the nanostructure device 20 is a PFET, and the source/drain regions 82 thereof include silicon germanium (SiGe). In some embodiments, NFETs and PFETs include the source/drain regions 82 having the same material at different doping levels to achieve operating characteristics of NFETs or PFETs. In some embodiments, the source/drain regions 82 include one or more of SiGeB, SiP, SiAs, SiGe, or another suitable semiconductive material. In some embodiments, the source/drain regions 82 have width (e.g., in the Y-axis) direction in a range of about 0.5 nm to about 100 nm (see FIG. 1). In some embodiments, height of the source/drain regions 82 (e.g., in the Z-axis direction) is in a range of about 0.1 nm to about 100 nm. The height of the source/drain regions 82 may be measured from an interface between a respective source/drain region 82 and the fin 32 on which it is disposed to a top of the source/drain region 82. In some embodiments, a bottom isolation layer 84 is disposed between the source/drain region 82 and the underlying fin structure 32. The bottom isolation layer 84 may be a dielectric material layer that includes an organic dielectric or an inorganic dielectric, such as a low-k dielectric or a high-k dielectric.

The channels 22 include a semiconductive material, for example silicon or a silicon compound, such as silicon germanium, or the like. The channels 22 are nanostructures (e.g., having sizes that are in a range of a few nanometers) and may also each have an elongated shape and extend in the X-direction. In some embodiments, the channels 22 have a nano-wire (NW) shape, a nano-sheet (NS) shape, a nano-tube (NT) shape, or other suitable nanoscale shape. The cross-sectional profile of the channels 22 (e.g., in the Y-Z plane) may be rectangular, round, square, circular, elliptical, hexagonal, or combinations thereof.

In some embodiments, the lengths (e.g., measured in the X-axis direction) of the channels 22 may be different from each other, for example due to tapering during an etching process that forms the fin structures 32. In some embodiments, length of the channel 22A1 may be less than a length of the channel 22B1, which may be less than a length of the channel 22C1. The channels 22 may not have uniform thickness, for example due to a channel trimming process used to expand spacing (e.g., measured in the Z-direction) between the channels 22 to increase fabrication process window for forming the gate structures 200. For example, a middle portion of each of the channels 22 may be thinner than the two ends of each of the channels 22. Such shape may be collectively referred to as a “dog-bone” shape.

In some embodiments, the spacing between the channels 22 (e.g., between the channel 22B1 and the channel 22A1 or the channel 22C1) is in a range of about 8 nanometers (nm) to about 12 nm. In some embodiments, a thickness (e.g., measured in the Z-direction) of each of the channels 22 is in a range of about 5 nm to about 8 nm. In some embodiments, a width (e.g., measured in the Y-direction, not shown in FIG. 1C, orthogonal to the X-Z plane) of each of the channels 22 is at least about 8 nm.

The gate structure 200 is disposed over and between the channels 22, respectively. In some embodiments, threshold voltage tuning is achieved by driving at least one specific dopant into one or more high-k gate dielectric layers 610 of the gate structure 200. In some embodiments, threshold voltage tuning is alternately or further achieved by adding one or more barrier layers (also referred to as “work function barrier layers”) in a work function metal layer between the high-k gate dielectric layer 610 and a metal core layer 290.

A first interfacial layer (IL) 210, which may be an oxide of the material of the channels 22, is disposed on exposed areas of the channels 22 and the top surface of the fin 32 when present. The first IL layer 210 promotes adhesion of the gate dielectric layer 610 to the channels 22. In some embodiments, the first IL layer 210 has thickness of about 5 Angstroms (Å) to about 50 Angstroms (Å). In some embodiments, the first IL layer 210 has thickness of about 10 A. The first IL layer 210 having thickness that is too thin may exhibit voids or insufficient adhesion properties. The first IL layer 210 being too thick consumes gate fill window, which is related to threshold voltage tuning and resistance as described above.

In some embodiments, the gate dielectric layer 610 includes a high-k gate dielectric material, which may refer to dielectric materials having a high dielectric constant that is greater than a dielectric constant of silicon oxide (k≈3.9). Example high-k dielectric materials include HfO₂, HfSiO, HfSiON, HfTaO, HfTiO, HfZrO, ZrO₂, Ta₂O₅, LaOx, AlOx, or combinations thereof. In some embodiments, the gate dielectric layer 610 includes dopants, such as metal ions driven into the high-k gate dielectric from La₂O₃, MgO, Y₂O₃, TiO₂, Al₂O₃, Nb₂O₅, or the like, or boron ions driven in from B₂O₃, at a concentration to achieve threshold voltage tuning.

The gate structure 200 may include one or more work function metal layers, such as an N-type work function metal layer, an in-situ capping layer, and an oxygen blocking layer. The gate structure 200 also includes metal core layer 290. The work function metal layers may be included in the metal core layer 290. The metal core layer 290 may include a conductive material such as tungsten, cobalt, ruthenium, iridium, molybdenum, copper, aluminum, or combinations thereof. Between the channels 22, the metal core layer 290 is circumferentially surrounded (in the cross-sectional view) by the gate dielectric layer 600.

Referring to FIG. 1C, distance D1 between adjacent stacks of nanostructures 22 (e.g., in the X-axis direction) may be in a range of about 0.5 nm to about 100 nm.

The nanostructure device 20A also includes gate spacers 41 and inner spacers 74 that are disposed on sidewalls of the gate dielectric layer 610. The inner spacers 74 are also disposed between the channels 22A1-22C1. The gate spacers 41 and the inner spacers 74 may include a dielectric material, for example a low-k material such as SiOCN, SiON, SiN, SiCN, SiO, or SiOC.

The nanostructure device 20A includes an interlayer dielectric (ILD) 130 and an etch stop layer (ESL) 131. The ILD 130 and the ESL 131 provide electrical isolation between various components of the nanostructure device 20, for example between the gate structure 200 and source/drain contacts 120.

The nanostructure device 20A are electrically connected to (e.g., in physical contact with) the source/drain contacts 120 that are disposed over the source/drain regions 82. The source/drain contacts 120 may include a conductive material such as tungsten, cobalt, ruthenium, iridium, molybdenum, copper, aluminum, TaN, TiN, or combinations thereof. The source/drain contacts 120 may be laterally surrounded by barrier layers (not shown), such as SiN or TiN, which help prevent or reduce diffusion of materials from and into the source/drain contacts 120. A silicide layer 118 may also be formed between the source/drain regions 82 and the source/drain contacts 120, so as to reduce the source/drain contact resistance. The silicide layer 118 may contain a metal silicide material, such as cobalt silicide in some embodiments, or TiSi in some other embodiments. Height of the source/drain contacts 120 (e.g., in the Z-axis direction) may be in a range of about 3 nm to about 150 nm. The source/drain contacts 120 may extend through a first ILD 140 and a first ESL 141, and through the ILD 130 and the ESL 131.

Optional conductive capping layers 204 may be disposed on the upper surfaces of the gate structures 200. The conductive capping layers 204 may include one or more of the conductive materials described above for the metal core layer 290. Gate vias 184 may be in contact with the gate structures 200 or optionally with the conductive capping layers 204, and may include one or more of the conductive materials described above for the metal core layer 290. The first ESL 141 may overlie and be in contact with the conductive capping layers 204. A second ILD 150 and a second ESL 151 may be disposed on the first ILD 140. The gate vias 184 may extend through the second ILD 150, the second ESL 151, the first ILD 140 and the first ESL 141. Source/drain vias 183 may extend through the second ILD 150 and the second ESL 151 to contact the source/drain contacts 120.

A third ILD 160 may be on the second ILD 150. An optional third ESL may be present between the third ILD 160 and the second ILD 150, and is not illustrated for simplicity. The frontside power line 280 may be disposed in the third ILD 160, and may be in contact with one or more of the source/drain vias 183, one or more of the gate vias 184, or both.

In some embodiments, the ILD 130, the first ILD 140, the second ILD 150 and the third ILD 160 may include one or more of silicon dioxide, carbon doped silicon dioxide, silicon oxynitride, borosilicate glass (BSG), phosphoric silicate glass (PSG), borophosphosilicate glass (BPSG), fluorinated silicate glass (FSG), a porous dielectric material, or the like. The ESL 131, the second ESL 141 and the third ESL 151 may be formed of silicon nitride, silicon carbo-nitride, or the like.

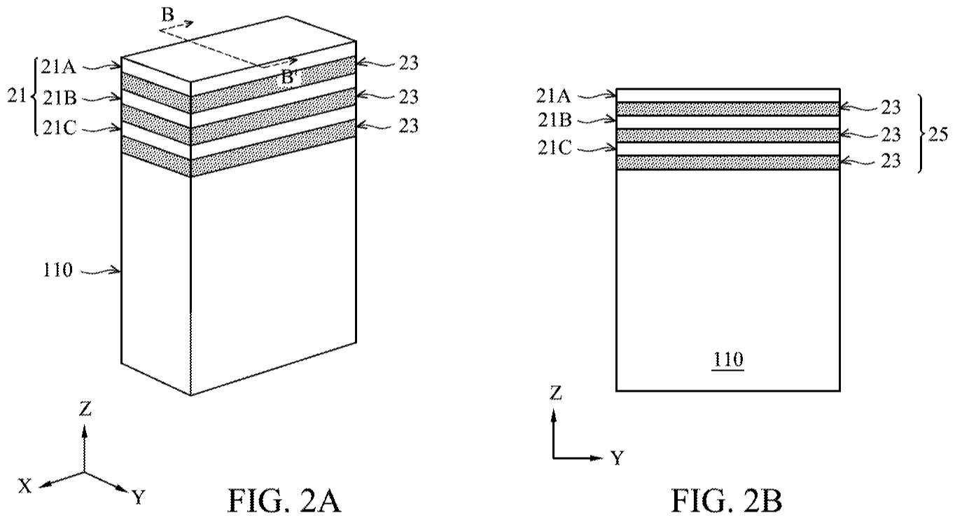

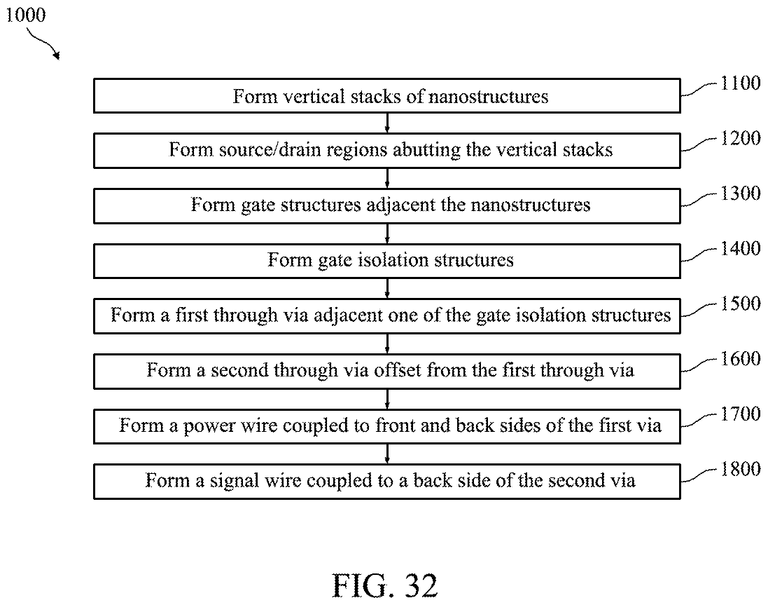

FIG. 32 illustrates a flowchart of a method 1000 for forming an IC device or a portion thereof from a workpiece, according to one or more aspects of the present disclosure. Method 1000 is merely an example and is not intended to limit the present disclosure to what is explicitly illustrated in method 1000. Additional acts can be provided before, during and after the method 1000 and some acts described can be replaced, eliminated, or moved around for additional embodiments of the methods. For example, the through vias 250, 254 may be formed from the frontside (e.g., prior to source/drain contact 120 formation) or from the backside (e.g., following source/drain contact 120 formation). Not all acts are described herein in detail for reasons of simplicity. Method 1000 is described below in conjunction with fragmentary cross-sectional views of a workpiece (shown in FIGS. 2A-11 and FIGS. 12-38) at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

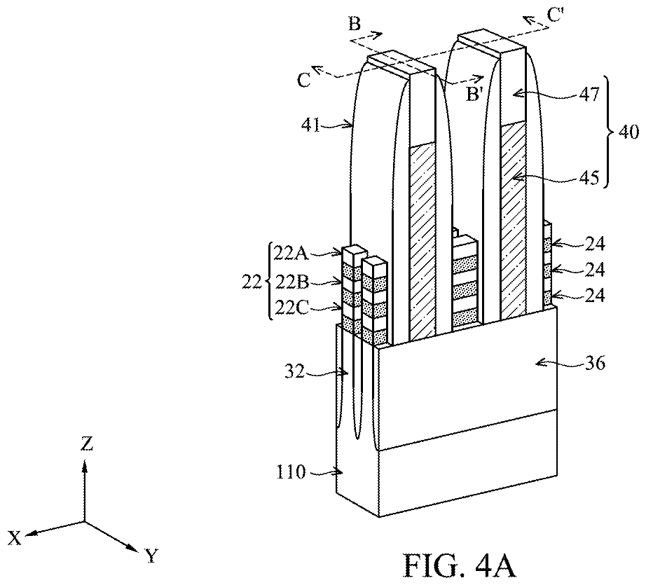

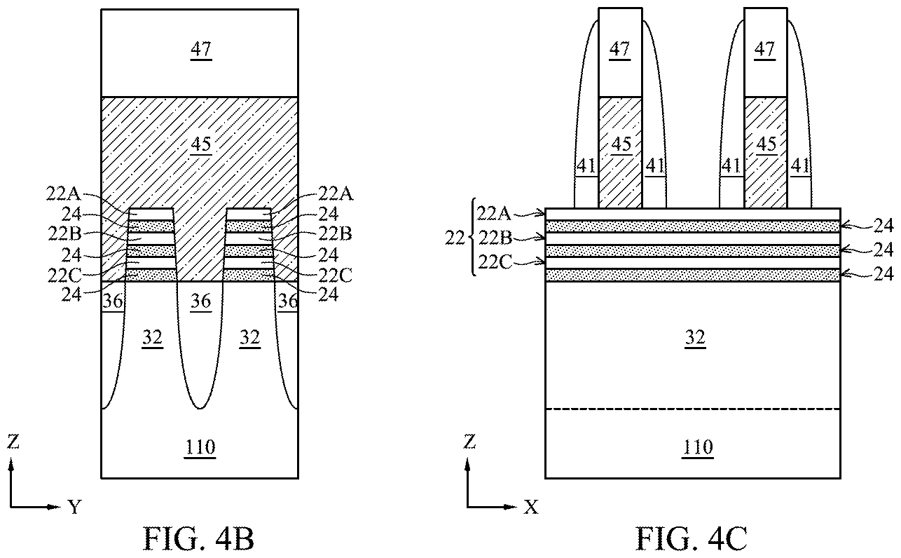

FIGS. 2A through 11 are diagrammatic perspective and cross-sectional side views of intermediate stages in the manufacturing of nanostructure devices including channels 22, source/drain regions 82 and gate structures 200, in accordance with some embodiments. FIGS. 2A, 3A, 4A, 5A, 6A, 7A, 8A, 9A, and 10A illustrate perspective views. FIGS. 2B, 3B, 4B, 5B, 6B, 7B, 8B, 9B, and 10B illustrate reference cross-section B-B′ (gate cut) illustrated in FIGS. 2A, 3A, and 4A. FIGS. 4C, 5C, 6C, 7C, 8C, 9C, 10C and 11 illustrate reference cross-section C-C′ (channel/fin cut) illustrated in FIG. 4A.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A-21C (collectively referred to as first semiconductor layers 21) and second semiconductor layers 23. In some embodiments, the first semiconductor layers 21 may be formed of a first semiconductor material suitable for n-type nano-FETs, such as silicon, silicon carbide, or the like, and the second semiconductor layers 23 may be formed of a second semiconductor material suitable for p-type nano-FETs, such as silicon germanium or the like. Each of the layers of the multi-layer stack 25 may be epitaxially grown using a process such as chemical vapor deposition (CVD), atomic layer deposition (ALD), vapor phase epitaxy (VPE), molecular beam epitaxy (MBE), or the like.

Three layers of each of the first semiconductor layers 21 and the second semiconductor layers 23 are illustrated. In some embodiments, the multi-layer stack 25 may include one or two each or four or more each of the first semiconductor layers 21 and the second semiconductor layers 23. For example, the IC device 10 shown in FIGS. 1A-1C include stacks of nanostructure channels 22 that have three channels 22 each. Although the multi-layer stack 25 is illustrated as including a second semiconductor layer 23 as the bottommost layer, in some embodiments, the bottommost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions 22 of nano-FETs. In some embodiments, the first semiconductor layers 21 are removed and the second semiconductor layers 23 are patterned to form channel regions 22. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions 22 of nano-FETs.

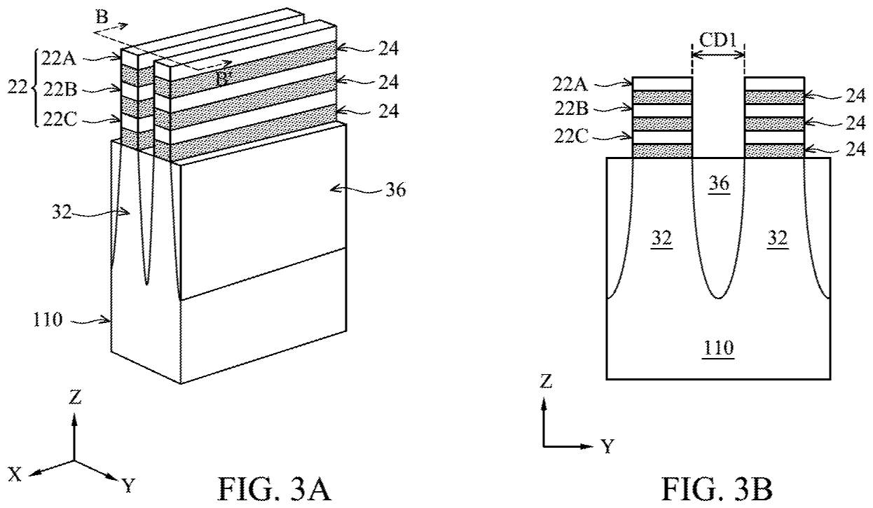

In FIG. 3A and FIG. 3B, fins or “fin structures” 32 are formed in the substrate 110 and nanostructures 22, 24 are formed in the multi-layer stack 25 corresponding to operation 1100 of FIG. 32. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A-22D (also referred to as “channels” below) are formed from the first semiconductor layers 21, and second nanostructures 24 are formed from the second semiconductor layers 23. Distance CD1 between adjacent fins 32 and nanostructures 22, 24 may be from about 18 nm to about 100 nm, although other distances CD1 that are less than 18 nm or greater than 100 nm are also contemplated embodiments herein.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions 36, which may be shallow trench isolation (STI) regions, are formed adjacent the fins 32 following formation of the trenches. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a fill or core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHf), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., an “etch first” process). The epitaxial structures may comprise the alternating semiconductor materials discussed above, such as the first semiconductor materials and the second semiconductor materials.

Further in FIGS. 3A and 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

In FIGS. 4A-4C, dummy or sacrificial gate structures 40 are formed over the fins 32 and/or the nanostructures 22, 24. A dummy or sacrificial gate layer 45 is formed over the fins 32 and/or the nanostructures 22, 24. The dummy gate layer 45 may be made of materials that have a high etching selectivity versus the isolation regions 36. The dummy gate layer 45 may be a conductive, semiconductive, or non-conductive material and may be or include one or more of amorphous silicon, polycrystalline-silicon (polysilicon), poly-crystalline silicon-germanium (poly-SiGe), metallic nitrides, metallic silicides, metallic oxides, and metals. The dummy gate layer 45 may be deposited by physical vapor deposition (PVD), CVD, sputter deposition, or other techniques for depositing the selected material. A mask layer 47 is formed over the dummy gate layer 45, and may include, for example, silicon nitride, silicon oxynitride, or the like. In some embodiments, a gate dielectric layer (not illustrated for simplicity) is formed before the dummy gate layer 45 between the dummy gate layer 45 and the fins 32 and/or the nanostructures 22, 24.

A spacer layer 41 is formed over sidewalls of the mask layer 47 and the dummy gate layer 45. The spacer layer 41 is made of an insulating material, such as silicon nitride, silicon oxide, silicon carbo-nitride, silicon oxynitride, silicon oxy carbo-nitride, or the like, and may have a single-layer structure or a multi-layer structure including a plurality of dielectric layers, in accordance with some embodiments. The spacer layer 41 may be formed by depositing a spacer material layer (not shown) over the mask layer 47 and the dummy gate layer 45. Portions of the spacer material layer between dummy gate structures 40 are removed using an anisotropic etching process, in accordance with some embodiments.

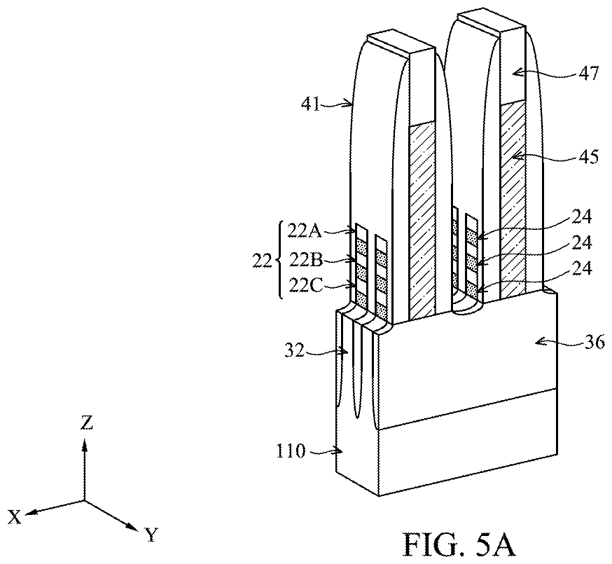

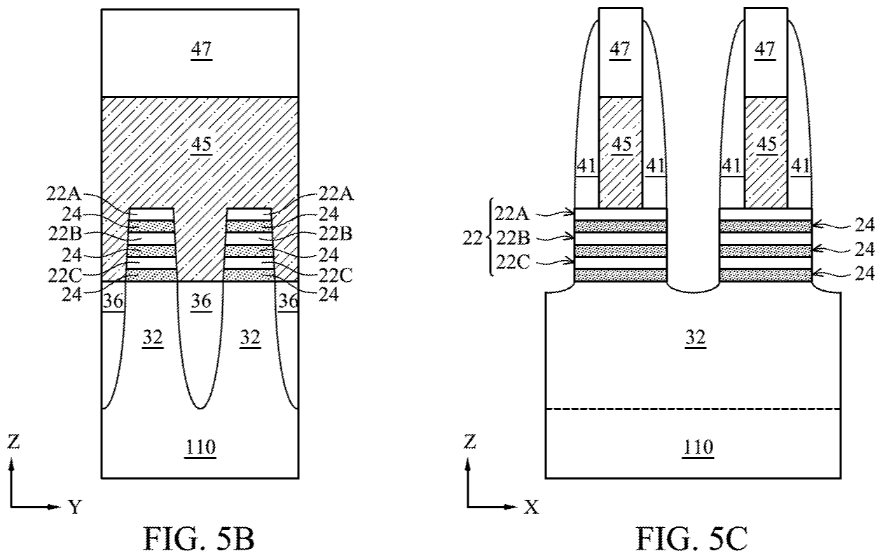

In FIGS. 5A-5C, an etching process is performed to etch the portions of protruding fins 32 and/or nanostructures 22, 24 that are not covered by dummy gate structures 40, resulting in the structure shown. The recessing may be anisotropic, such that the portions of fins 32 directly underlying dummy gate structures 40 and the spacer layer 41 are protected, and are not etched. The top surfaces of the recessed fins 32 may be substantially coplanar with the top surfaces of the isolation regions 36 as shown, in accordance with some embodiments. The top surfaces of the recessed fins 32 may be lower than the top surfaces of the isolation regions 36, in accordance with some other embodiments.

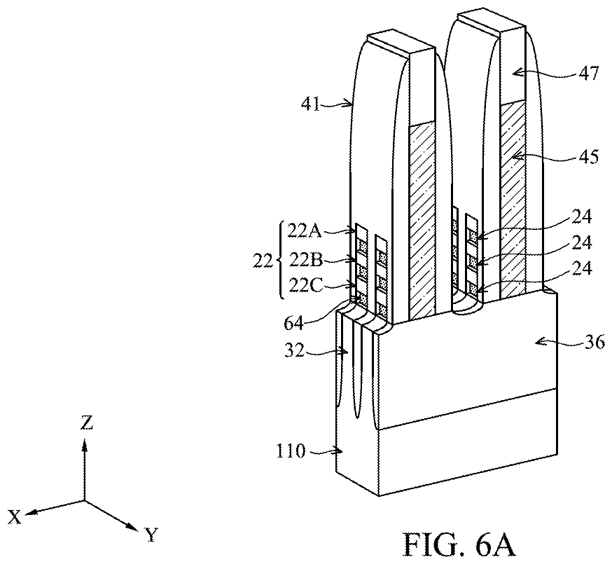

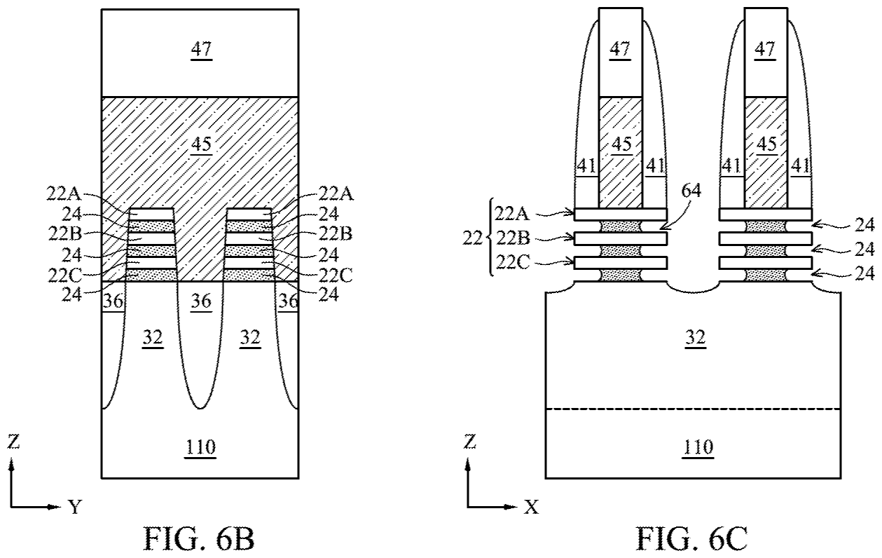

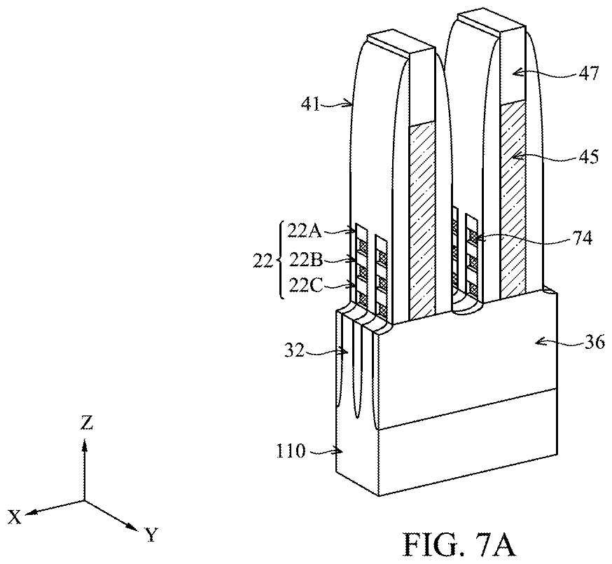

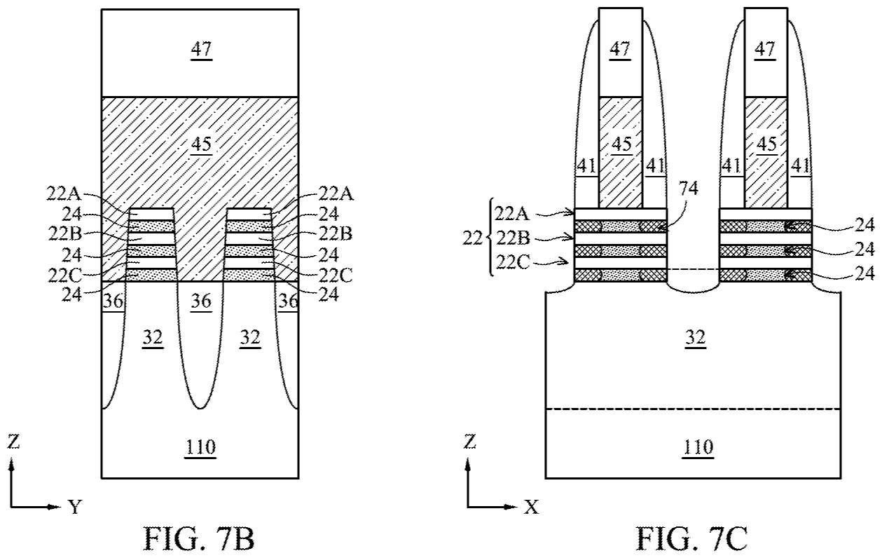

FIGS. 6A-6C and 7A-7C illustrate formation of inner spacers 74. A selective etching process is performed to recess end portions of the nanostructures 24 exposed by openings in the spacer layer 41 without substantially attacking the nanostructures 22. After the selective etching process, recesses 64 are formed in the nanostructures 24 at locations where the removed end portions used to be. The resulting structure is shown in FIGS. 6A-6C.

Next, an inner spacer layer is formed to fill the recesses 64 in the nanostructures 22 formed by the previous selective etching process. The inner spacer layer may be a suitable dielectric material, such as silicon carbon nitride (SiCN), silicon oxycarbonitride (SiOCN), or the like, formed by a suitable deposition method such as PVD, CVD, ALD, or the like. An etching process, such as an anisotropic etching process, is performed to remove portions of the inner spacer layers disposed outside the recesses in the nanostructures 24. The remaining portions of the inner spacer layers (e.g., portions disposed inside the recesses 64 in the nanostructures 24) form the inner spacers 74. The resulting structure is shown in FIGS. 7A-7C.

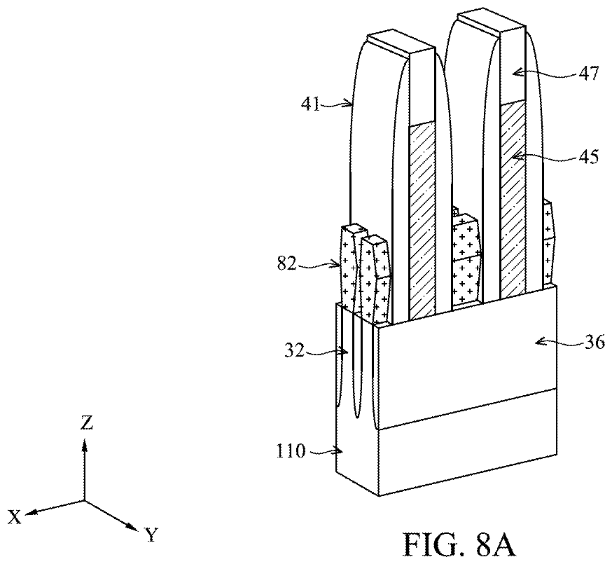

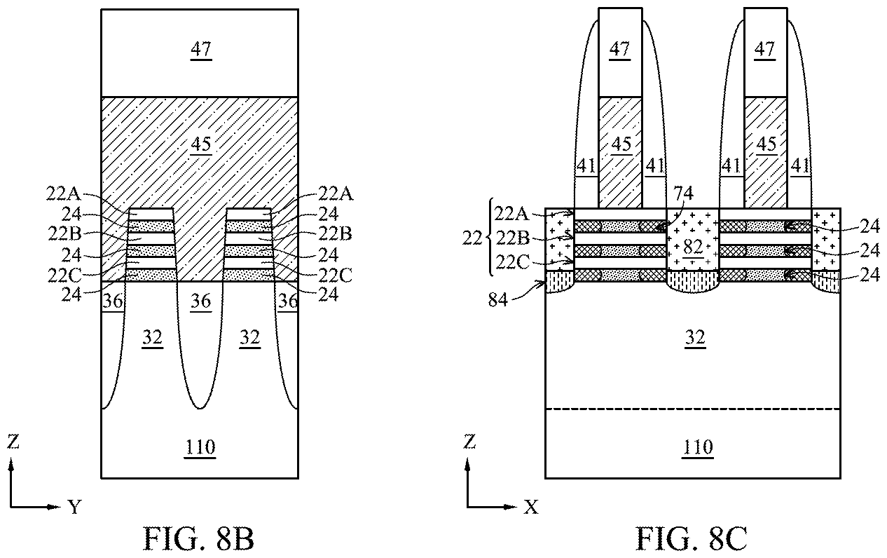

FIGS. 8A-8C illustrate formation of bottom isolation layer 84 and source/drain regions 82 corresponding to operation 1200 of FIG. 32. The bottom isolation layer 84 is formed on a bottom surface of the S/D trenches. Formation of the bottom isolation layer 84 may include various processes. Referring to FIG. 8C, first, an isolation layer is deposited over the dummy gate structures 40, along the sidewalls of the gate spacers 41 and in the S/D trenches. In some embodiments, the isolation layer includes a dielectric material having a different selectivity from the gate spacers 41. For example, the isolation layer includes an isolation material such as SiO, SiN, aluminum oxide (Al₂O₃), other isolation material, or combinations thereof. The isolation layer can be deposited by CVD, PVD, ALD, other suitable process, or combinations thereof. The isolation layer has a thickness over the bottom surface of the S/D trenches (e.g., the exposed surface of the fin structure 32 in the S/D trenches) that is in a range of about 1 nm to about 10 nm, such that the isolation layer is thin enough to leave enough space for the future formed S/D feature and is thick enough to ensure the isolation function over the recessed fin portion in the S/D region. The isolation layer being too thin may cause the bottom isolation layer 84 to be broken during later etching process(es), such that the S/D feature may be epitaxially grown from the fin structure 32 and cause bulk leakage therebetween.

In the illustrated embodiment, the source/drain regions 82 are epitaxially grown from epitaxial material(s). When the bottom isolation layer 84 is present, the source/drain regions 82 may grow epitaxially outward from sidewalls of the channels 22, and may merge in the space laterally between the channels 22 in the S/D trenches. In some embodiments, the source/drain regions 82 exert stress in the respective channels 22A-22C, thereby improving performance. The source/drain regions 82 are formed such that each dummy gate structure 40 is disposed between respective neighboring pairs of the source/drain regions 82. In some embodiments, the spacer layer 41 separates the source/drain regions 82 from the dummy gate layer 45 by an appropriate lateral distance to prevent electrical bridging to subsequently formed gates of the resulting device.

The source/drain regions 82 may include any acceptable material, such as appropriate for n-type or p-type devices. For n-type devices, the source/drain regions 82 include materials exerting a tensile strain in the channel regions, such as silicon, SiC, SiCP, SiP, SiAs or the like, in some embodiments. When p-type devices are formed, the source/drain regions 82 include materials exerting a compressive strain in the channel regions, such as SiGe, SiGeB, Ge, GeSn, or the like, in accordance with certain embodiments. The source/drain regions 82 may have surfaces raised from respective surfaces of the fins and may have facets. Neighboring source/drain regions 82 may merge in some embodiments to form a singular source/drain region 82 adjacent two neighboring fins 32.

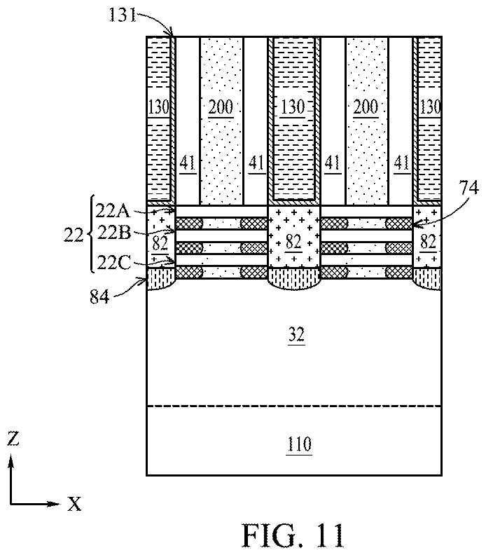

The source/drain regions 82 may be implanted with dopants followed by an anneal. The source/drain regions may have an impurity concentration of between about 10¹⁹ cm⁻³ and about 10²¹ cm⁻³. N-type and/or p-type impurities for source/drain regions 82 may be any of the impurities previously discussed. In some embodiments, the source/drain regions 82 are in situ doped during growth. A contact etch stop layer (CESL) and interlayer dielectric (TLD), not illustrated in FIG. 8C for simplicity, may then be formed covering the dummy gate structures 40 and the source/drain regions 82 (see FIG. 11).

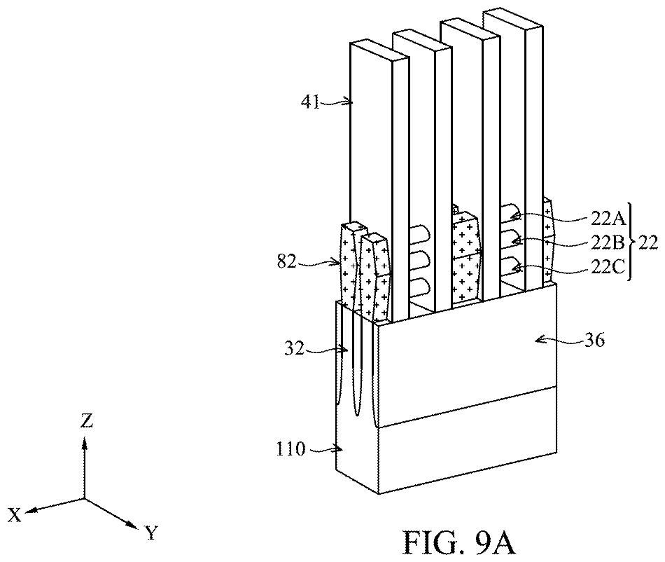

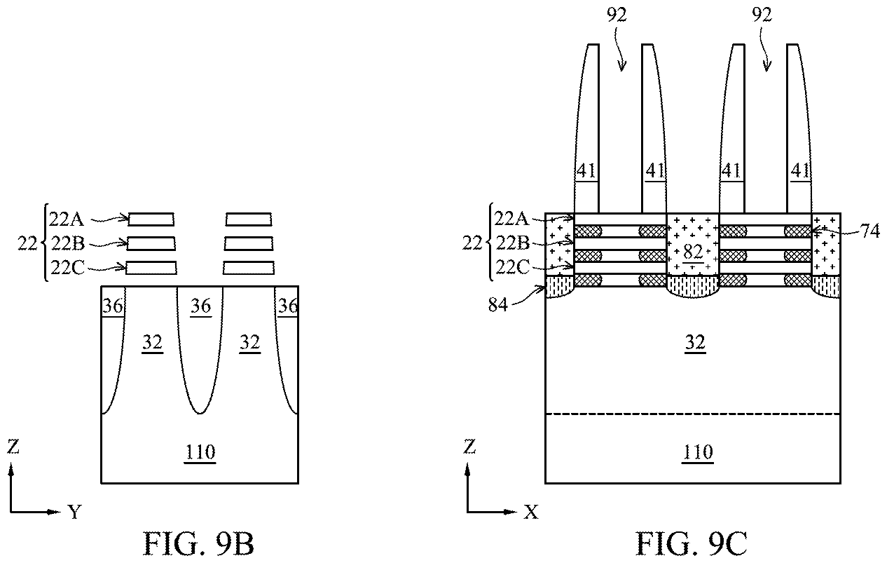

FIGS. 9A-9C illustrate release of fin channels 22A-22C by removal of the nanostructures 24, the mask layer 47, and the dummy gate layer 45, which corresponds to act 1500 of FIG. 11. A planarization process, such as a CMP, is performed to level the top surfaces of the dummy gate layer 45 and gate spacer layer 41. The planarization process may also remove the mask layer 47 (see FIG. 8A) on the dummy gate layer 45, and portions of the gate spacer layer 41 along sidewalls of the mask layer 47. Accordingly, the top surfaces of the dummy gate layer 45 are exposed.

Next, the dummy gate layer 45 is removed in an etching process, so that recesses 92 are formed. In some embodiments, the dummy gate layer 45 is removed by an anisotropic dry etch process. For example, the etching process may include a dry etch process using reaction gas(es) that selectively etch the dummy gate layer 45 without etching the spacer layer 41. The dummy gate dielectric, when present, may be used as an etch stop layer when the dummy gate layer 45 is etched. The dummy gate dielectric may then be removed after the removal of the dummy gate layer 45.

The nanostructures 24 are removed to release the nanostructures 22. After the nanostructures 24 are removed, the nanostructures 22 form a plurality of nanosheets that extend horizontally (e.g., parallel to a major upper surface of the substrate 110). The nanosheets may be collectively referred to as the channels 22 of the nanostructure device 20 formed.

In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of the nanostructure devices 20 that are NFETs, and the nanostructures 22 may be removed and the nanostructures 24 may be patterned to form channel regions of the nanostructure devices 20 that are PFETs. In some embodiments, the nanostructures 22 may be removed and the nanostructures 24 may be patterned to form channel regions of the nanostructure devices 20 that are NFETs, and the nanostructures 24 may be removed and the nanostructures 22 may be patterned to form channel regions of the nanostructure devices 20 that are PFETs. In some embodiments, the nanostructures 22 may be removed and the nanostructures 24 may be patterned to form channel regions of both PFETs and NFETs.

In some embodiments, the nanosheets 22 of the nanostructure device 20 are reshaped (e.g. thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction.

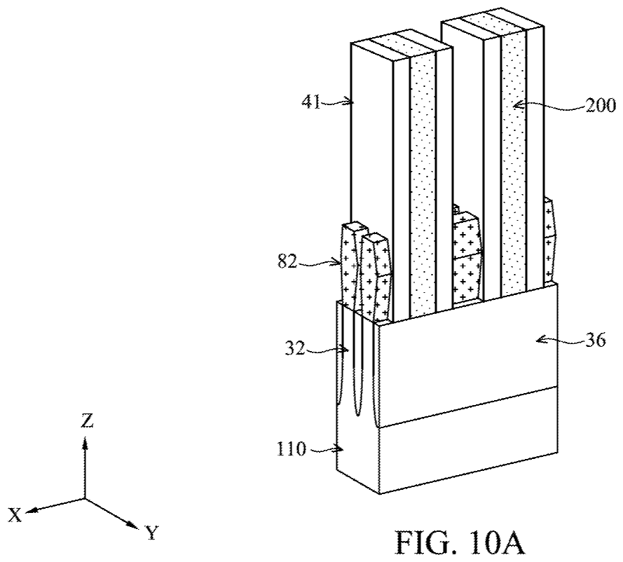

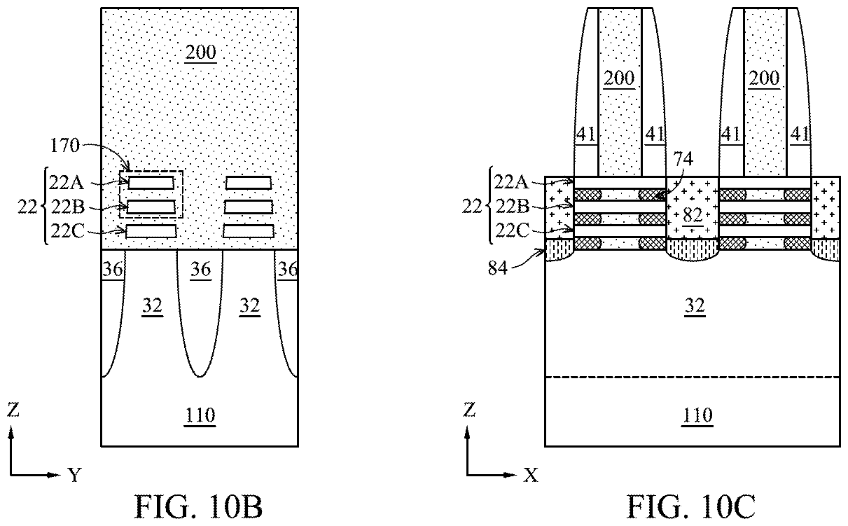

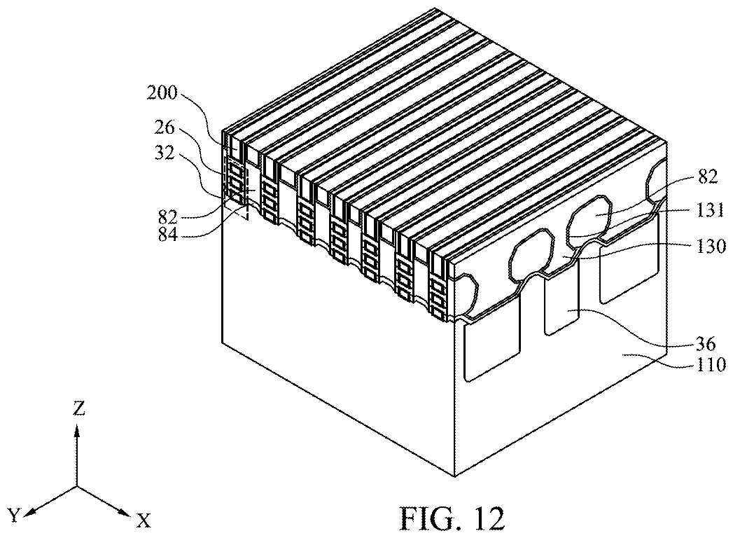

Next, in FIGS. 10A-10C, gate structures 200 are formed, corresponding to operation 1300 of FIG. 32. Each gate structure 200 may include the first IL layer 210, the high-k dielectric layer 610, and the metal core layer 290. Following deposition of materials of the gate structures 200, a removal operation, such as a CMP, may be performed to remove excess materials of the gate structures 200 overlying the ILD 130. The resulting structure is shown in FIGS. 11 and 12.

FIGS. 12-38 are views of various embodiments of an IC device at various stages of forming through vias for backside power and signal routing in accordance with various embodiments.

FIGS. 12-19D are views of forming the power vias 254 and signal via 250 in accordance with various embodiments.

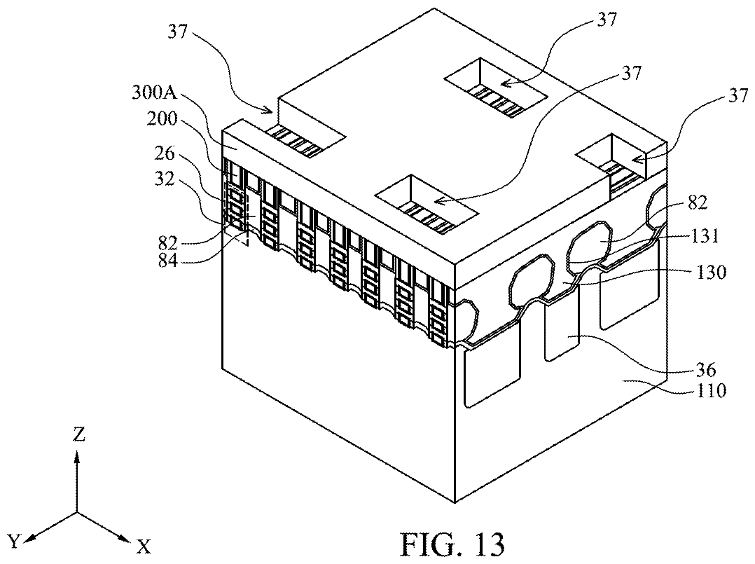

FIG. 12 is a diagrammatic perspective view of the IC device formed as described with reference to FIGS. 2A-11 above. The IC device at the operation illustrated in FIG. 12 may include a substrate 110 having fins 32 thereon that extend in a first direction (e.g., the X-axis direction), are arranged in a second direction (e.g., the Y-axis direction) transverse the first direction, and have vertical stacks 26 of nanostructure channels 22 thereon. Gate structures 200 extend in the second direction, are arranged in the first direction, and cover and wrap around the channels 22. Source/drain regions 82 abut the channels 22 on either side along the first direction. The fins 32 are isolated from each other by isolation regions 36 arranged along the second direction. Each of the source/drain regions 82 is above a respective fin 32, and is optionally isolated from the respective fin by bottom isolation layer 84. The source/drain regions 82 are isolated from each other in the second direction by ILD 130 and ESL 131. The gate structures 200 are isolated from each other in the first direction by the ILD 130 and the ESL 131. To form IC cells that perform electrical functions, such as a static random-access memory (SRAM) cell that stores digital data, the gate structures 200 may be “cut” to form openings, and isolation structures may be formed in the openings. The through vias 250, 254 may be formed between and/or in the isolation structures, in some embodiments, as will be described in greater detail with reference to FIGS. 13-19D.

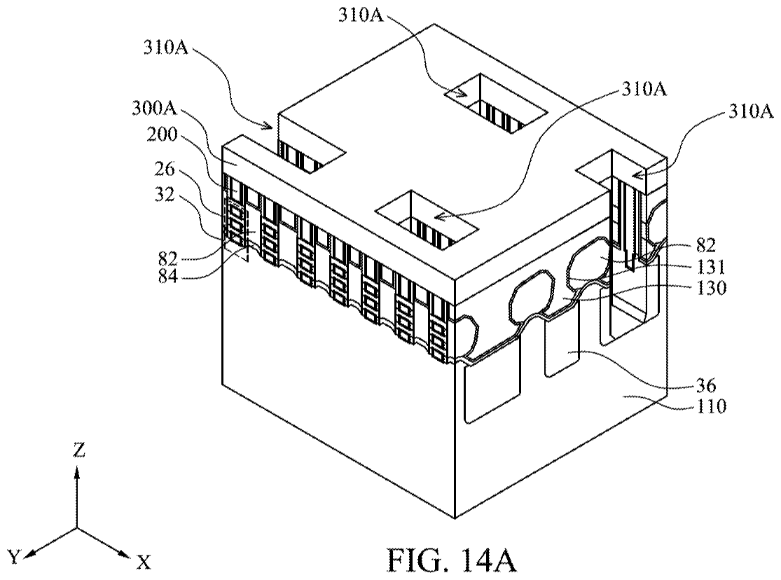

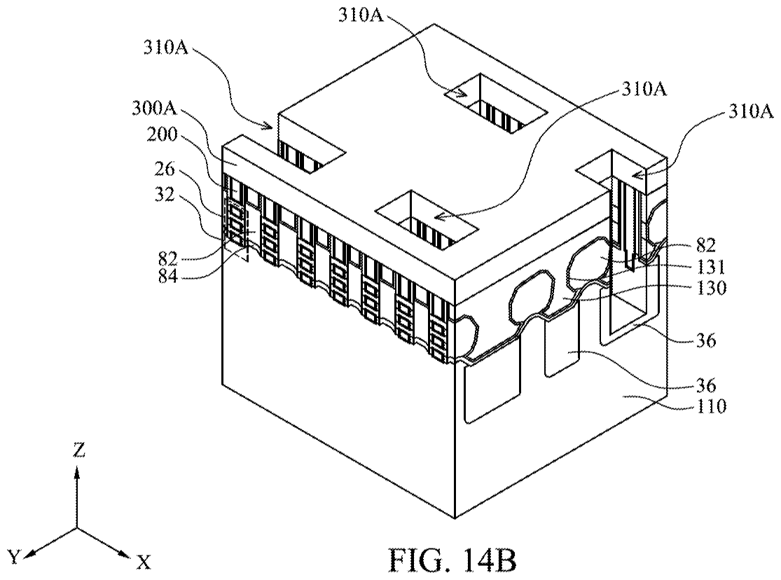

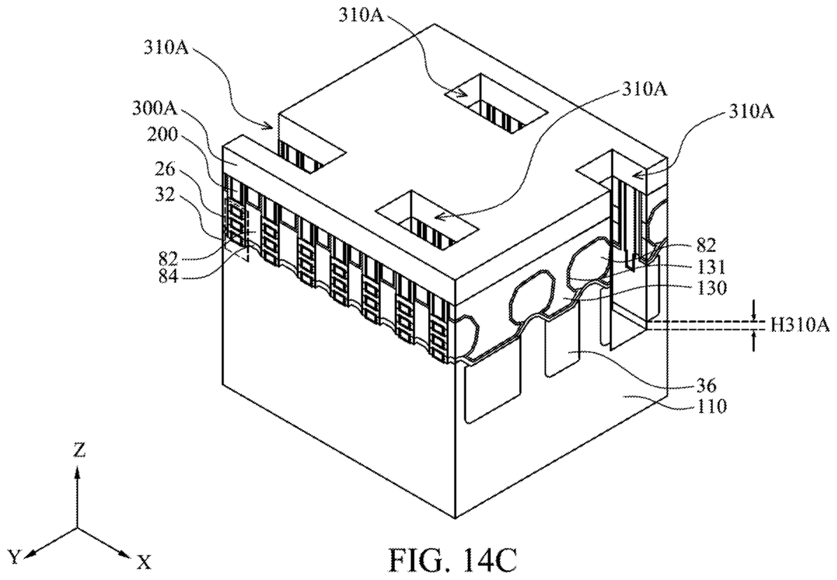

In FIG. 13, following formation of the gate structures 200, a first mask layer 300A is formed on the ILD 130 and the gate structures 200, which may include formation of one or more mask layers. In some embodiments, the first mask layer 300A is or includes a hard mask layer and one or more of a photoresist layer, an anti-reflective coating layer, or the like. The first mask layer 300A may include a dielectric material, such as a nitride, e.g., SiN, SiCN, SiOC, SiOCN, or the like. Openings 37 corresponding to the power vias 254 are formed in portions of the first mask layer 300A exposed by a photolithography operation. The openings 37 may correspond to gate isolation regions in which gate isolation structures 99 will be formed in later operations. The openings 37 may have width in the Y-axis direction that is in a range of about 30 nm to about 180 nm. Below about 30 nm, residue may remain in openings 310A due to insufficient space to cut the underlying structure sufficiently. Formation of the openings 310A is described with reference to FIGS. 14A-14C below.

In FIGS. 14A-14C, portions of the IC device 10 exposed by the openings 37 in the first mask layer 300A are then etched through the first mask layer 300A to form openings or “first openings” 310A. One or more suitable etching operations may be performed to form the openings 310A by removing material of the ILD 130, the gate structures 200, the isolation regions 36 and the substrate 110. The openings 310A may extend through the ILD 130, the gate structures 200 and the isolation regions 36, and may land on the substrate 110, as shown in FIG. 14A. In some embodiments, as shown in FIG. 14B, formation of the openings 310A stops at a point prior to exposing the substrate 110, such that the openings 310A extend into the isolation regions 36, but do not break through the isolation regions 36. In the embodiment illustrated in FIG. 14B, thickness of a horizontal portion of the isolation region 36 in the bottom of the opening 310A may be in a range of about 1 nm to about 30 nm. In some embodiments, as shown in FIG. 14C, the openings 310A extend into the substrate 110, for example, when the etching operation does not stop when the substrate 110 is exposed, but continues for a selected time after exposing the substrate 110. Distance H310A shown in FIG. 14C is extension of the opening 310A past the lower surface of the isolation region 36 and/or past the upper surface of the substrate 110. In some embodiments, distance H310A may be in a range of about 1 nm to about 30 nm. The embodiment of FIG. 14B may be advantageous in reducing aspect ratio (e.g., width/height) of the first openings 310A, which may improve process window for depositing dielectric material of the gate isolation structures 99 in subsequent operations.

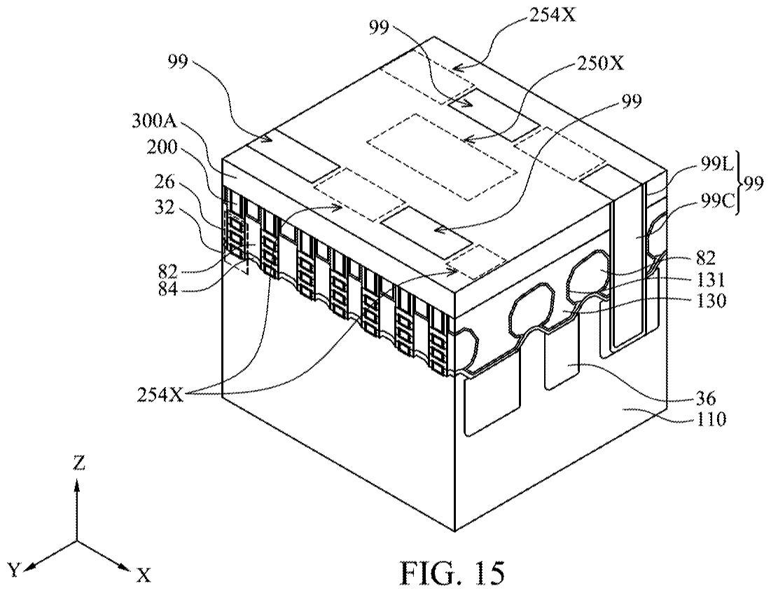

In FIG. 15, gate isolation structures 99 are formed in the openings 310A, corresponding to operation 1400 of FIG. 32. The gate isolation structures 99 may include a liner layer 99L and a core layer 99C. In some embodiments, the liner layer 99L is or includes a nitride, and may be the same material as that of the first mask layer 300A. In some embodiments, the liner layer 99L is SiN. The liner layer 99L is deposited as a conformal layer on exposed regions of the IC device in the first openings 310A and on the first mask layer 300A. The core layer 99C may be or include an oxide, such as silicon oxide. The liner layer 99L is between the core layer 99C and the adjacent features of the IC device, and is advantageous to block the oxide from diffusing to the adjacent features. In some embodiments, the liner layer 99L is in contact with the core layer 99C. Following formation of the liner layer 99L and the core layer 99C, excess materials of the liner layer 99L and the core layer 99C overlying the first mask layer 300A may be removed by a removal operation, such as a CMP. Regions 250A, 254A illustrated in phantom in FIG. 15 correspond to regions in which through vias 250, 254, respectively, will be formed in subsequent operations.

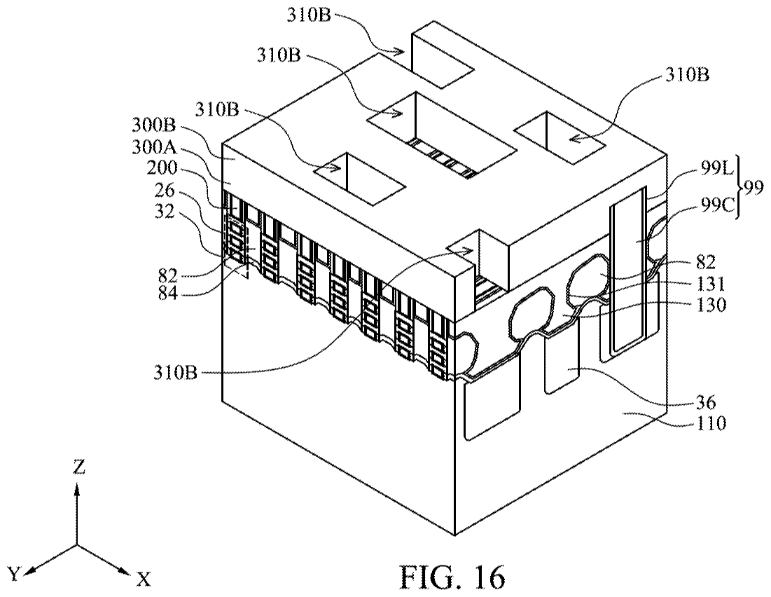

In FIG. 16, optional second mask layer 300B is formed over the first mask layer 300A and the gate isolation structures 99, then patterned to form openings or “second openings” 310B and openings or “third openings” 310C that expose portions of the IC device in which through vias 254, 250 will be formed in subsequent operations. The second openings 310B and third opening 310C may be extended through the first mask layer 300A by one or more suitable etching operations. The second mask layer 300B may include one or more photoresist layers, anti-reflective coating layers, hard mask layers, or the like. In some embodiments, the second mask layer 300B is not formed, and the openings 310B, 310C are formed by patterning the first mask layer 300A directly. Inclusion of the second mask layer 300B may be advantageous when remaining thickness of the first mask layer 300A is insufficient following formation of the gate isolation structures 99. In some embodiments, the second mask layer 300B is or includes the same material as the first mask layer 300A. In some embodiments, the second openings 310B are substantially aligned with the gate isolation structures 99. In some embodiments, the second openings 310B have substantially the same width in the Y-axis direction as the gate isolation structures 99. In some embodiments, the second openings 310B partially overlap and expose the gate isolation structures 99. The second openings 310B may be disposed at a boundary region that is between adjacent IC cells. The third opening 310C may be disposed in one of the IC cells, for example, in a middle or central region thereof. The second and third openings 310B, 310C may each have width in the Y-axis direction that is in a range of about 30 nm to about 180 nm. The width being greater than about 30 nm is advantageous to provide sufficient space for filling a conductive material of the through vias 250, 254 in subsequent operations.

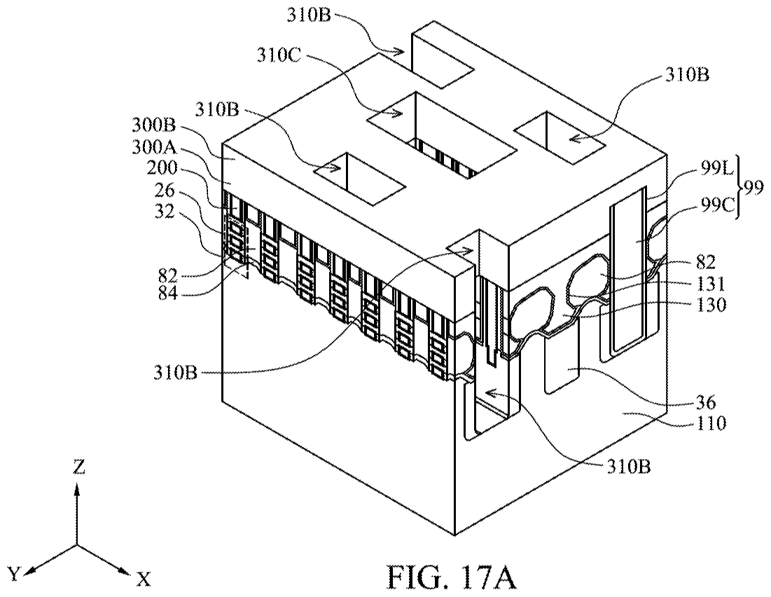

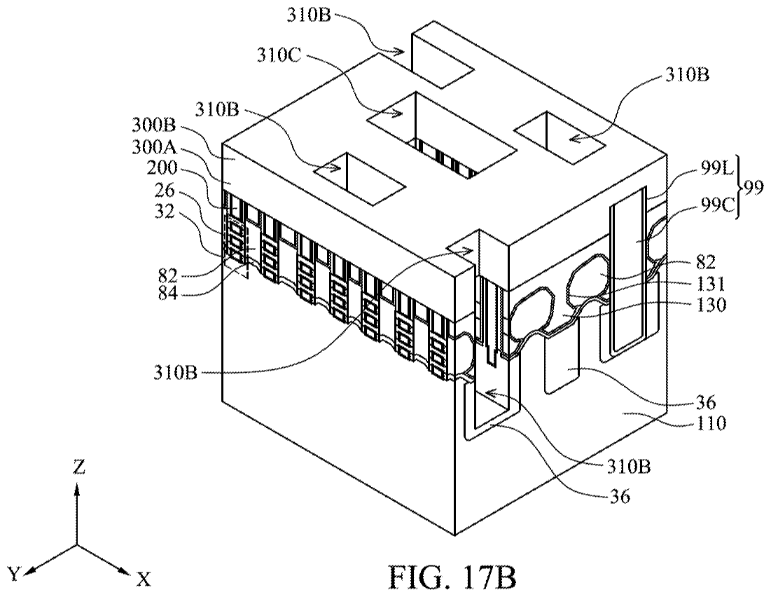

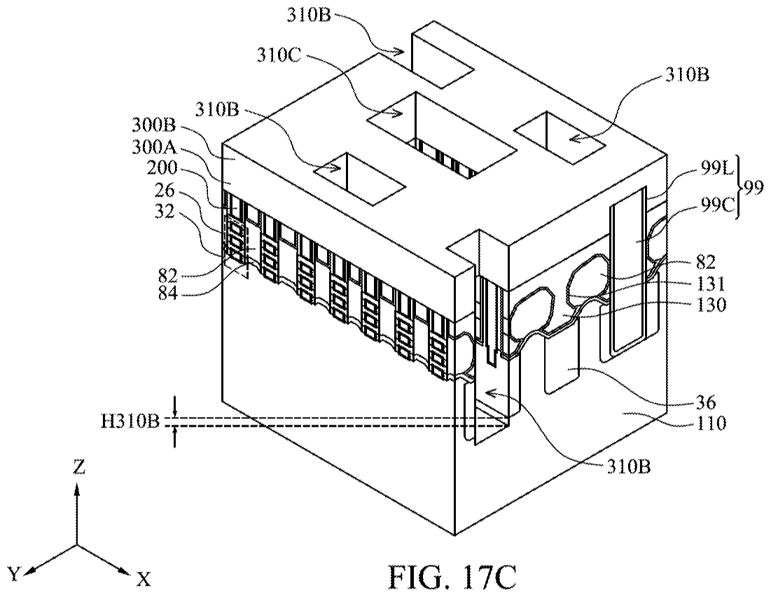

In FIGS. 17A-17C, the second and third openings 310B, 310C are extended by etching exposed portions of the IC device through the second mask layer 300B. In some embodiments, the exposed portions are etched by one or more anisotropic etching operations. As shown in FIG. 17A, the second and third openings 310B, 310C may extend through the isolation regions 36 until the substrate 110 is exposed, and may land on the substrate 110. As shown in FIG. 17B, the second and third openings 310B, 310C may extend partially into the isolation regions 36 without exposing the substrate 110, such that horizontal portions of the respective isolation regions 36 remain in the second and third openings 310B, 310C. The horizontal portions may have thickness in the Z-axis direction that is in a range of about 1 nm to about 30 nm. As shown in FIG. 17C, the second and third openings 310B, 310C may extend through the isolation regions 36 and partially into the substrate 110, for example, when the etching operation continues after the substrate 110 is exposed. The second and third openings 310B, 310C may extend to a depth H310B beyond an upper surface of the substrate 110 and/or beyond a lower surface of the isolation region 36 that is in a range of about 1 nm to about 30 nm. The embodiment of FIG. 17B may be advantageous in reducing aspect ratio (e.g., width/height) of the second and third openings 310B, 310C, which may improve process window for depositing conductive material of the through vias 250, 254 in subsequent operations.

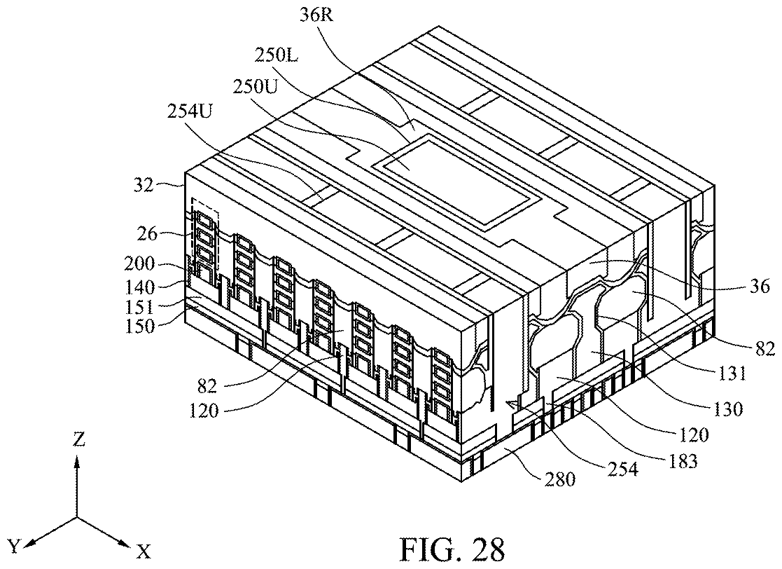

It should be understood that, while not in view in FIGS. 17A-17C, the fins 32 on either side of the third opening 310C may have jog (see FIG. 28) to increase space for accommodating the through via 250. That way, the etch that forms the third opening 310C has less opportunity to etch into neighboring source/drain regions 82, which is advantageous to reduce defects.

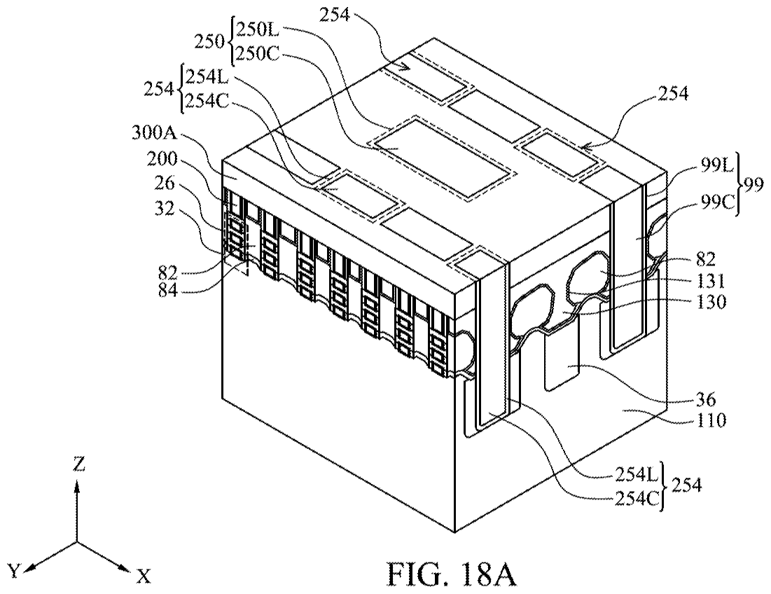

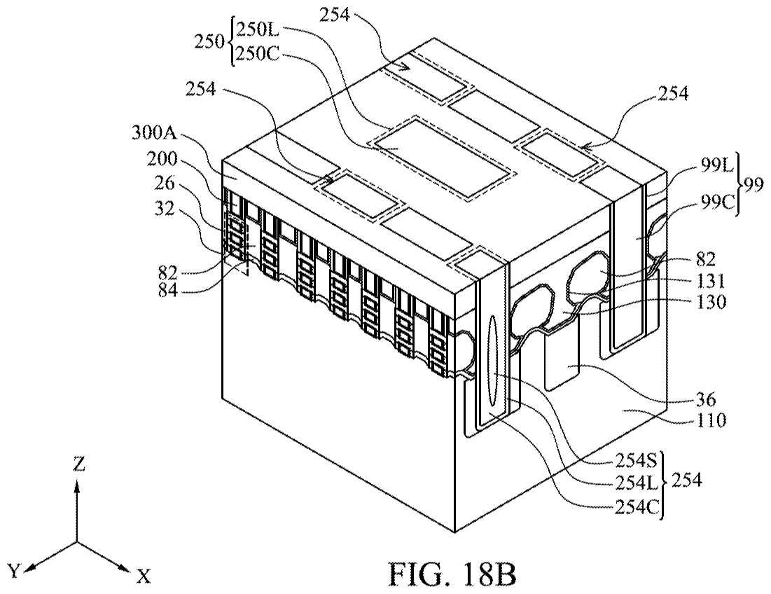

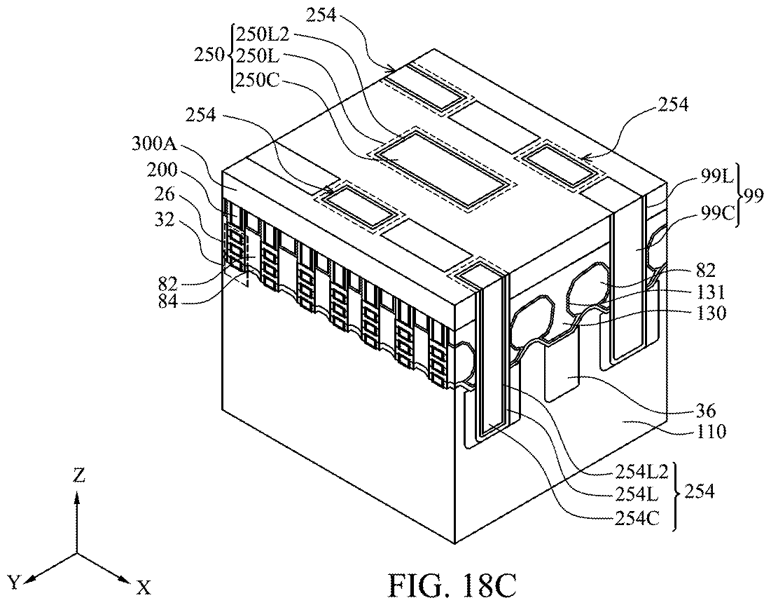

In FIGS. 18A-18C, material of the through vias 250, 254 is deposited in the second and third openings 310B, 310C formed by the process described with reference to FIGS. 17A-17C, corresponding to operations 1500 and 1600 of FIG. 32. Operations 1500 and 1600 are performed simultaneously. The material of the through vias 250, 254 may be deposited by one or more PVD, CVD, ALD, sputtering, or other suitable deposition operations. In some embodiments, liner layers 250L, 254L are deposited, followed by core layers 250C, 254C. The liner layers 250L, 254L may be deposited in the same operation, and may include the same material, which may be a nitride dielectric, such as SiN, SiCN, or the like. The liner layers 250L, 254L are advantageous to isolate the core layers 250C, 254C from adjacent features of the IC device. In some embodiments, the liner layers 250L, 254L have thickness in a range of about 5 nm to about 20 nm. The core layers 250C, 254C may be deposited in the same operation, and may include the same material, which may be a conductive material, such as TiN, W, Ru, Mo, Co, or the like. Following deposition of the material of the through vias 250, 254 in the second and third openings 310B, 310C, one or more removal operations, such as a CMP, may be performed to remove the second mask layer 300B. The removal operations may expose the gate isolation structures 99. As shown in FIG. 18B, the core layers 250C, 254C may be formed with one or more seams or voids therein. A seam 254S of one of the through vias 254 is illustrated in FIG. 18B. A similar seam may be present in the through via 250, even if not specifically illustrated. As shown in FIG. 18C, the through vias 250, 254 may include optional barrier layers 250L2, 254L2 that are formed prior to the core layers 250C, 254C. The barrier layers 250L2, 254L2 may include the same material, which may be a conductive material, such as Ti, Ta, TiN, TaN, or the like.

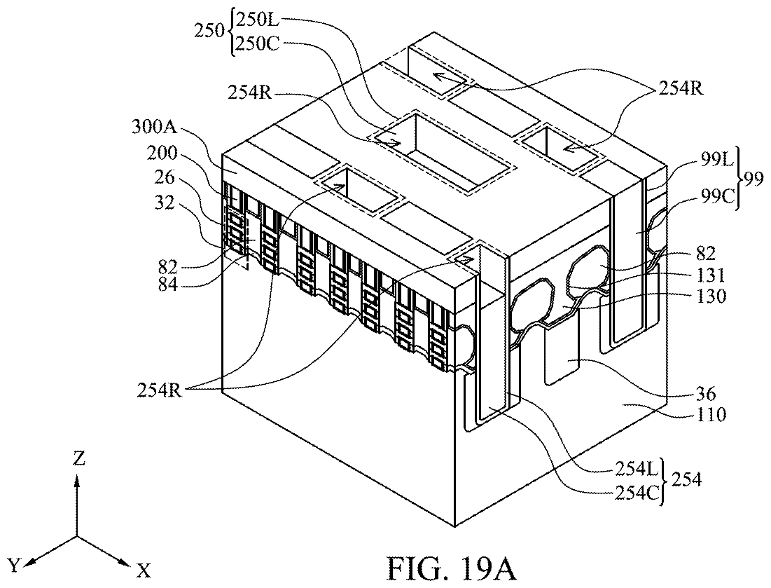

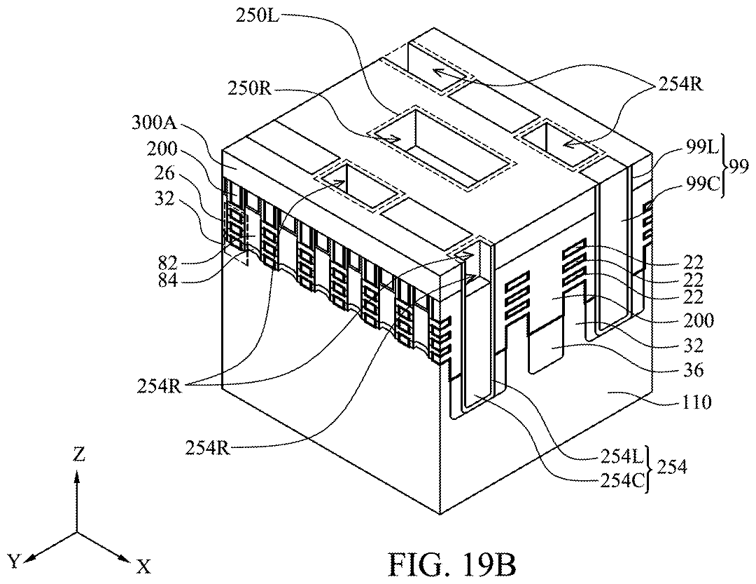

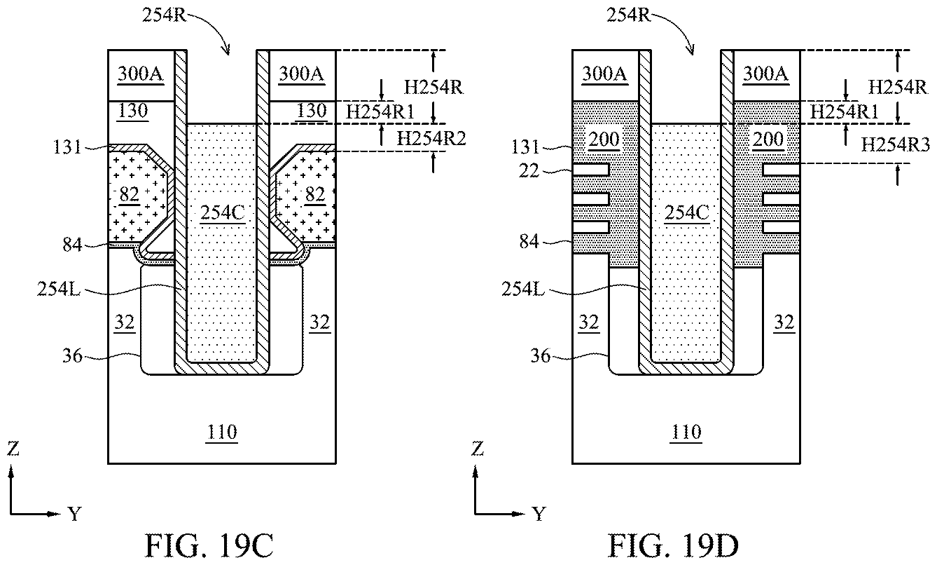

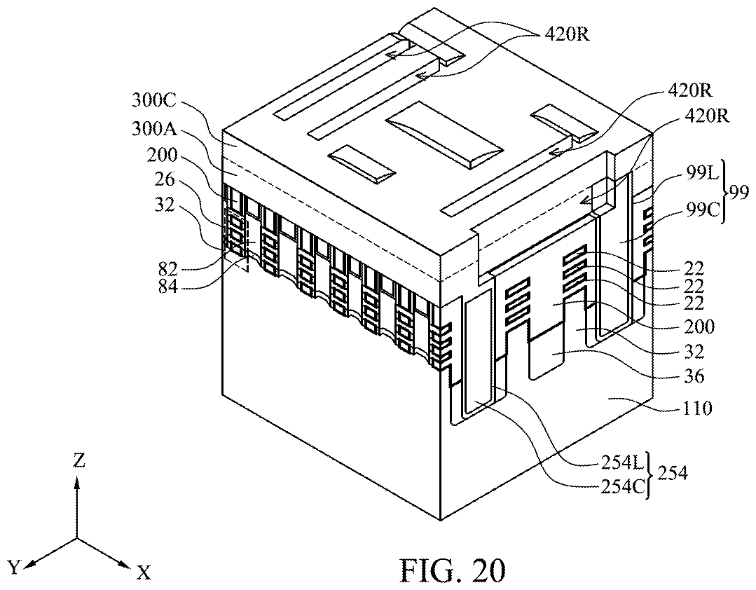

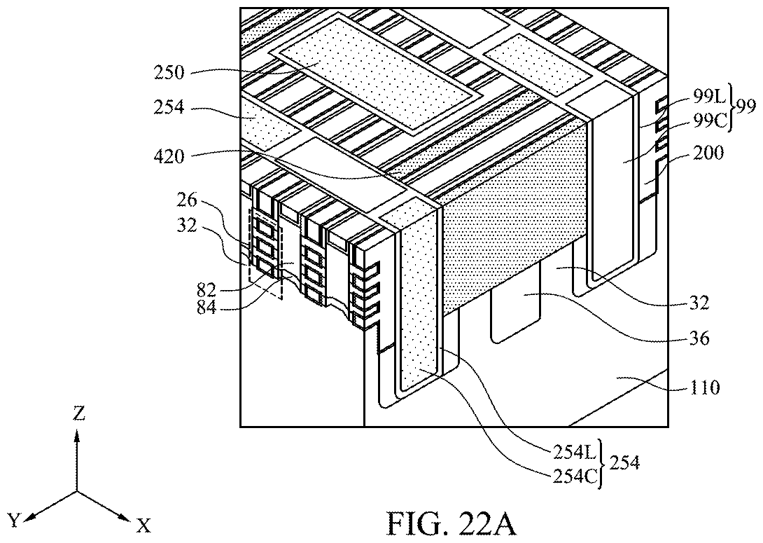

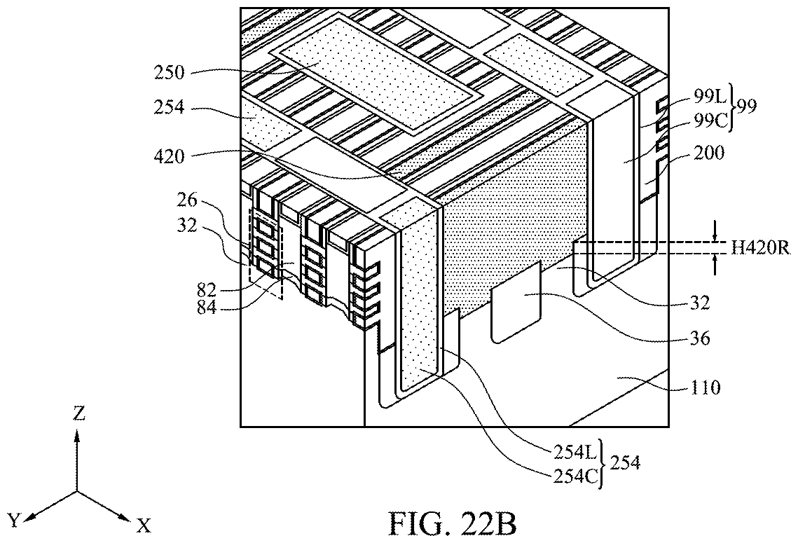

In FIGS. 19A-19D, following formation of the through vias 250, 254, the through vias 250, 254 may be recessed to form openings 250R, 254R. Recessing of the through vias 250, 254 may include recessing the core layers 250C, 254C and the optional barrier layers 250L2, 254L2 (when present) by one or more suitable etching operations that are selective to materials of the core layers 250C, 254C and/or the optional barrier layers 250L2, 254L2 without substantially attacking the materials of the gate isolation structures 99, the first mask layer 300A and optionally the liner layers 250L, 254L, when present. The core layers 250C, 254C being recessed to a level lower than the top surface of the gate structures 200 is advantageous for protecting the core layers 250C, 254C in subsequent etching processes that form an opening 420R (see FIG. 20) for an isolation structure 420, which may be referred to as a continuous poly on oxide diffusion edge or “CPODE” 420 (see FIG. 22).

FIGS. 19C, 19D illustrate dimensions H254R, H254R1, H254R2, H254R3 of the recess 254R, and description will be given with reference thereto. The recess 250R may have the same or very similar dimensions as the dimensions H254R, H254R1, H254R2, H254R3. As shown in FIG. 19D, the dimension H254R is overall depth of the recess, e.g. distance between the upper surface of the core layer 254C and the upper surface of the first mask layer 300A. The dimension H254R1 is distance between the upper surface of the core layer 254C and the upper surface of the gate structure 200. The dimension H254R1 may be in a range of about 10 nm to about 20 nm. The dimension H254R1 being greater than about 10 nm is advantageous to protect the core layers 250C, 254C from being exposed during etching processes used for forming the CPODE 420. The dimensions H254R2 and H254R3 are distances between the upper surface of the core layer 254C and upper surfaces of the source/drain regions 82 and upper surfaces of the uppermost channels 22, respectively. It is beneficial for the dimensions H254R2, H254R3 to be greater than about 1 nm, so that a CMP operation used to expose the gate structures 200 and the through vias 250, 254 following formation of the CPODE 420 does not expose the source/drain regions 82 and leaves a portion of the gate structures 200 overlying the uppermost channels 22. In some embodiments, the dimensions H254R2, H254R3 are greater than about 1 nm, about 2 nm, about 5 nm, about 10 nm, or another suitable dimension.

FIGS. 20-23 are diagrammatic plan views of forming the CPODE 420 in accordance with various embodiments. The CPODE 420 may be merged with one or more transistors in a standard cell layout, and is advantageous to achieve higher density and smaller corner variations such as mobility variations caused by process variations for cells placed at different locations on a same chip or for chips placed at different locations on a same wafer. Corner variations are the result of non-uniformities in a manufacturing process which result in devices having variations in performance characteristics. In some embodiments, the CPODE 420 is not formed.

In FIG. 20, a third mask layer 300C is formed on the first mask layer 300A, the gate isolation structures 99 and the through vias 250, 254. The third mask layer 300C extends into the recesses 250R, 254R, which is advantageous for protecting the through vias 250, 254 when the third mask layer 300C is etched for forming openings 420R. The third mask layer 300C may be or include a hard mask layer, such as a dielectric nitride, e.g., SiN, SiCN, or the like. In some embodiments, the third mask layer 300C is the same material as the first mask layer 300A.

Following formation of the third mask layer 300C, the openings 420R are formed by patterning the third mask layer 300C and etching through the first mask layer 300A and the underlying structure exposed by the third mask layer 300C, as shown in FIG. 20. In some embodiments, the openings 420R are first formed to a depth that exposes the gate structures 200. During etching to form the openings 420R, exposed portions of the gate isolation structures 99 may be recessed, as shown. Due to presence of the third mask layer 300C over the through vias 250, 254, the etching operation stops well in advance of exposing the core layers 250C, 254C, as shown.

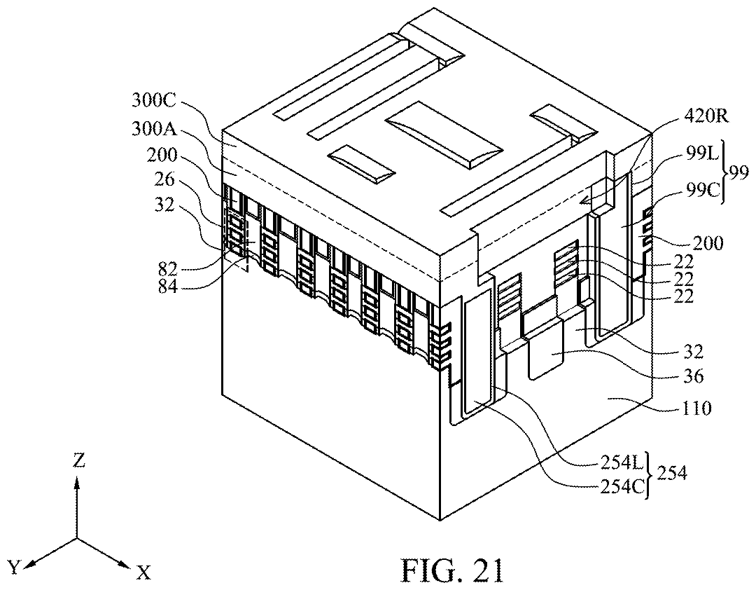

In FIG. 21, after exposing the gate structures 200, the openings 420R are extended downward by one or more subsequent etching operations that remove material of the gate structures 200, the channels 22, the fin structures 32 and optionally the isolation regions 36 without substantially attacking material of the third mask layer 300C. In some embodiments, a first etching operation is performed to remove exposed portions of the gate structures 200. The first etching operation may be a wet etching operation. In some embodiments, a second etching operation following the first operation is performed to remove exposed portions of the channels 22 and the fin structures 32 until the isolation regions 36 are exposed. The second etching operation may be a dry etching operation.

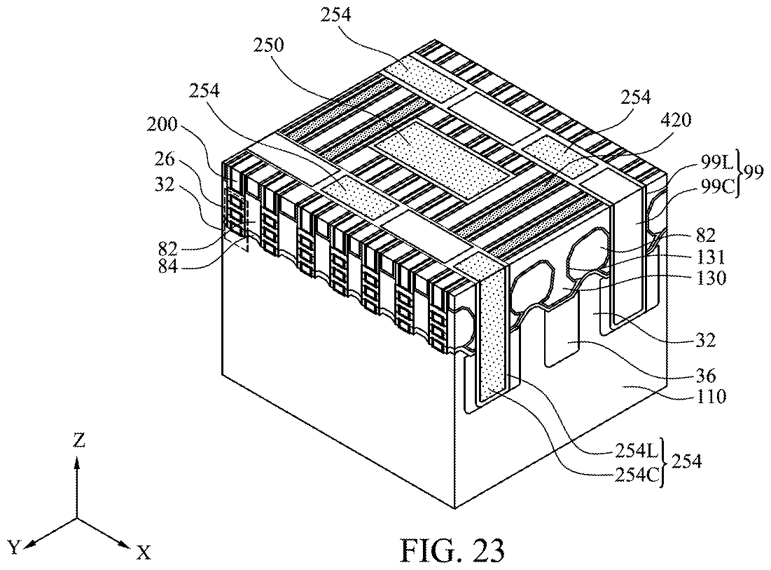

In FIGS. 22A, 22B, 23, following extending of the openings 420R, isolation structures 420 are formed in the openings 420R. The CPODE 420 may be or include a low-k dielectric material, such as SiO, SiN, SiCN, SiON, SiOCN, or the like, which may be deposited by a suitable deposition operation, such as a PVD, CVD, ALD, or the like. The dielectric material of the CPODE 420 may be different or the same as that of the gate isolation structure 99. Following formation of the CPODE 420, a CMP may be performed to remove the third mask 300C and the first mask 300A, thereby exposing the through vias 250, 254 and the gate structures 200, as shown in FIG. 22A. In some embodiments, the second etching operation described with reference to FIG. 21 removes the fin structures 32 to a depth that is slightly lower than the top surface of the isolation regions 36. In such embodiments, the resulting structure following formation of the CPODE 420 is shown in FIG. 22B. Namely, the CPODE 420 inherits the shape of the opening 420R, and may extend partially below the top surface of the isolation regions 36, as shown. FIG. 23 is a diagrammatic plan view of the IC device including the CPODE 420 in another view.

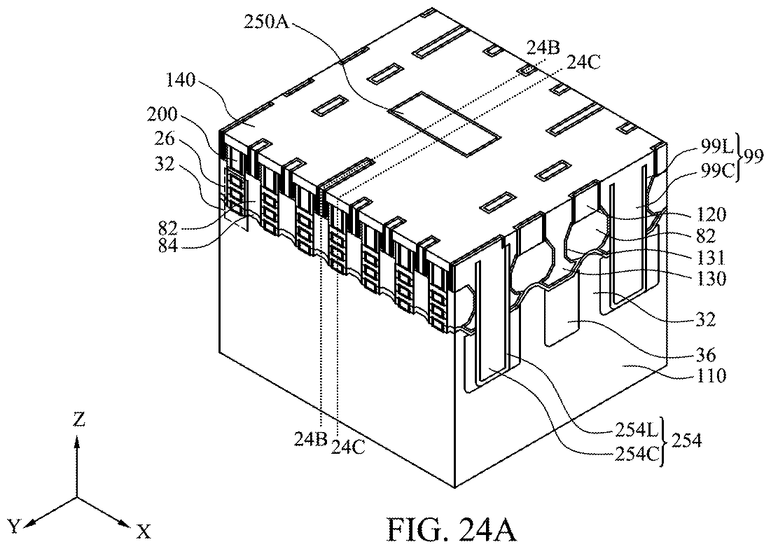

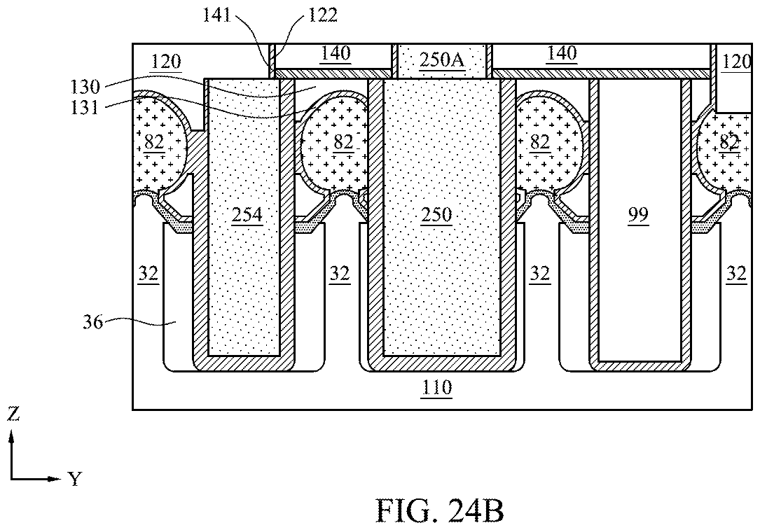

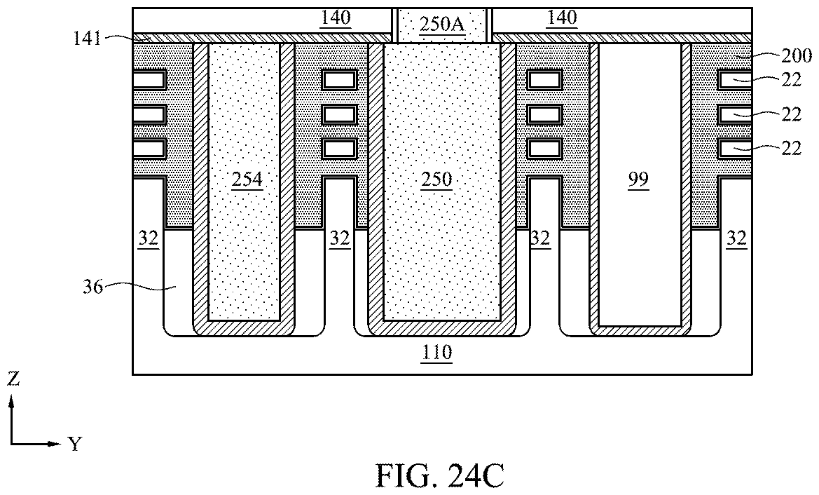

FIGS. 24A-26 are diagrammatic perspective and cross-sectional side views illustrating formation of frontside electrical interconnect features in accordance with various embodiments.

In FIG. 24A, a first ESL 141 and a first ILD 140 are formed on the upper surface of the structure shown in FIG. 23. The first ESL 141 may be deposited as a conformal thin layer on the upper surfaces of the gate structures 200, through vias 250, 254, gate isolation structures 99, ILD 130, ESL 131, CPODE 420, and sidewall spacers 41. Following formation of the first ESL 141, the first ILD 140 may be formed on the first ESL 141. The first ESL 141 and the first ILD 140 may each be formed by suitable deposition processes, such as one or more of a PVD, CVD, ALD, or the like.

Thereafter, the first ILD 140 is patterned to form openings in which source/drain contacts 120 and a first through via layer 250A are formed. In some embodiments, various photoresist lithography and etching processes may be performed to the first ILD 140 to form the openings. For example, a patterned photoresist mask is formed over the first ILD 140. Subsequently, one or more etching processes are performed using the patterned photoresist mask to remove the exposed portions of the first ILD 140. The etching process(es) may stop on the first ESL 141. Thereafter, a subsequent etching process may be performed to break through the first ESL 141 and expose upper surfaces of the through vias 250, 254 and the ILD 130. After exposing the upper surfaces of the ILD 130, yet another etching process may be performed to remove exposed portions of the ILD 130 to expose the ESL 131. Then, a further etching process may be performed to remove the ESL 131, thereby exposing the source/drain regions 82.

As shown in FIG. 24B, the etching processes described above may form at least one single opening that exposes both the source/drain region 82 and the adjacent power via 254. Others of the openings may only expose the source/drain region 82, such as the right-side source/drain region 82 adjacent the gate isolation region 99. The etching processes may also form an opening that exposes the upper surface of the signal via 250, as shown in FIGS. 24B, 24C.

Source/drain contacts 120 may then be formed in the openings over the source/drain regions 82 and optionally over the power vias 254. The first through via layer 250A is formed in the opening over the signal via 250. In some embodiments, the first through via layer 250A has width in the Y-axis direction that is less than that of the signal via 250, which may be advantageous to avoid bridging between the first through via layer 250A and the neighboring gate structures 200.

Formation of the source/drain contacts 120 and the first through via layer 250A may include one or more deposition processes. In some embodiments, an isolation layer 122 is formed in the openings prior to forming the source/drain contacts 120 and the first through via layer 250A. For example, the isolation layer 122 may be deposited as a thin, conformal layer over sidewalls of the first ILD 140 and the ILD 130. Then, a suitable etching operation may be performed to remove portions of the isolation layer 122 overlying the source/drain regions 82, so as to expose the source/drain regions 82. Following formation of the isolation layer 122, one or more barrier layers (not shown) may be deposited, such as a layer of TiN, which adheres well to materials of the source/drain contacts 120 and the first through via layer 250A, as well as to materials of the first ILD 140 and the ILD 130. A silicide layer 118 may be formed by an annealing operation that causes material of the source/drain regions 82 and the barrier layers to form a silicide at an interface therebetween, such as cobalt silicide in some embodiments, or TiSi or TiSiN in some other embodiments. The source/drain contacts 120 may include a conductive core material, which may be formed by depositing a conductive material, such as tungsten, cobalt, ruthenium, iridium, molybdenum, copper, aluminum, or combinations thereof on the source/drain regions 82, the silicide layer 118, the barrier layer(s), or a combination thereof. A CMP operation may be performed following deposition of the source/drain contacts 120 and the first through via layer 250A to remove excess material of the source/drain contacts 120 and the first through via layer 250A from over the first ILD 140.

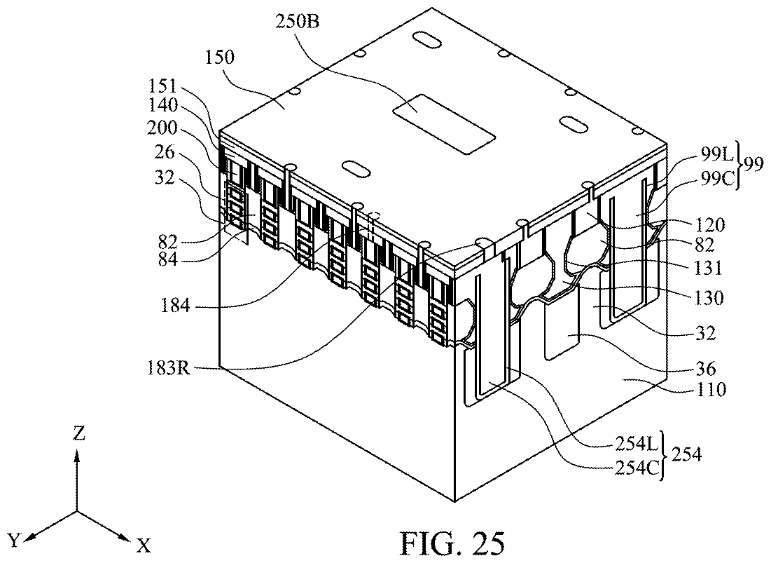

In FIG. 25, a second ESL 151 and a second ILD 150 are formed over the first ILD 140, the source/drain contacts 120 and the first through via layer 250A. The second ESL 151 may be deposited as a conformal thin layer on the upper surfaces of the first ILD 140, the source/drain contacts 120 and the first through via layer 250A. Following formation of the second ESL 151, the second ILD 150 may be formed on the second ESL 151. The second ESL 151 and the second ILD 150 may each be formed by suitable deposition processes, such as one or more of a PVD, CVD, ALD, or the like.

Thereafter, the second ILD 150 is patterned to form openings in which source/drain contacts 120 and a first through via layer 250A are formed. In some embodiments, various photoresist lithography and etching processes may be performed to the second ILD 150 to form the openings. For example, a patterned photoresist mask is formed over the second ILD 150. Subsequently, one or more etching processes are performed using the patterned photoresist mask to remove the exposed portions of the second ILD 150. The etching process(es) may stop on the second ESL 151. Thereafter, a subsequent etching process may be performed to break through the second ESL 151 and expose upper surfaces of the source/drain contacts 120 and the first through via layer 250A.

Following formation of openings exposing the source/drain contacts 120 and the first through via layer 250A, source/drain vias (VD) 183, expanded source/drain vias (VDR) 183R and a second through via layer 250B are formed in the openings. The source/drain vias (VD) 183, expanded source/drain vias (VDR) 183R and second through via layer 250B may be formed by depositing a conductive material in the openings. The conductive material may be or include W, Ru, Co, Cu, Mo, or the like, and may be deposited by a suitable process, such as a PVD, CVD, ALD, or the like. In some embodiments, the source/drain vias (VD) 183, expanded source/drain vias (VDR) 183R and second through via layer 250B are the same material as the source/drain contacts 120 and the first through via layer 250A. The second through via layer 250B may also be referred to as an expanded source/drain via 250B. In some embodiments, gate vias 184 are formed in the same deposition process as the source/drain vias 183, expanded source/drain vias 183R and the second through via layer 250B. For example, location where the gate via 184 may be located is illustrated in phantom in FIG. 25.

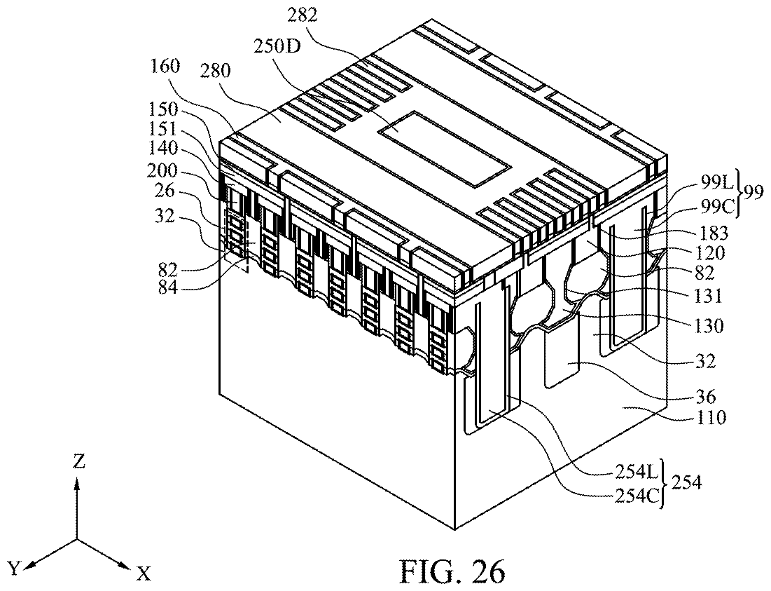

In FIG. 26, a metallization layer of a frontside interconnect structure 108 (see FIG. 1C) that may be referred to as a back-end-of-line (BEOL) interconnect structure 108 is formed. The metallization layer may include a third ILD 160 and conductive features disposed therein. The conductive features may include a frontside power wire 280, a third through via layer 250C, and other local interconnect traces 282. In some embodiments, a third ESL is present between the third ILD 160 and the second ILD 150. The third ILD 160 may be patterned by a process similar to that used to pattern the first ILD 140 and/or the second ILD 150, thereby forming openings in which the conductive features are formed. The conductive features may be or include W, Ru, Co, Cu, Mo, or the like, and may be formed by a suitable process, such as a PVD, CVD, ALD, or the like. Additional metallization layers may be formed in a similar fashion on top of the metallization layer shown in FIG. 26. The BEOL interconnect structure 108 at the frontside of the IC device may include at least two metallization layers, such as eight, ten, or more metallization layers similar to that shown in FIG. 26.

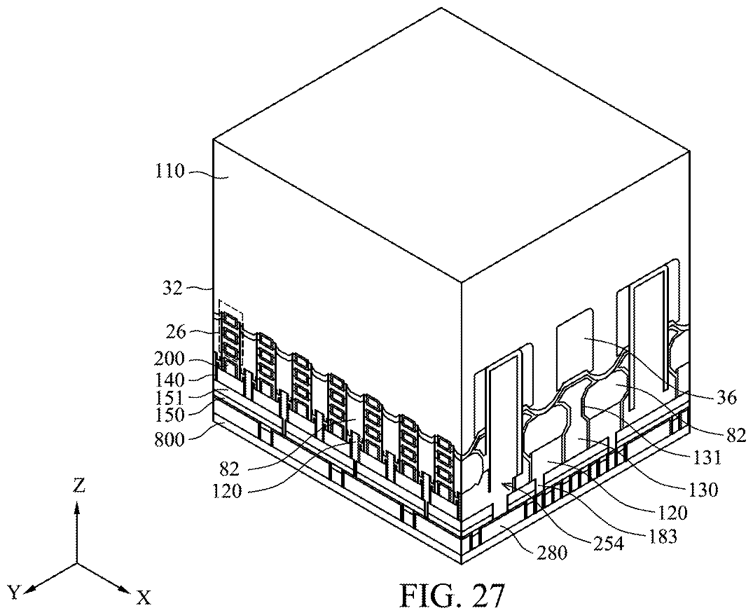

FIGS. 27-29 are diagrammatic perspective and cross-sectional side views illustrating formation of frontside electrical interconnect features in accordance with various embodiments.

In FIG. 27, the IC device may be flipped, such that the bottom side of the substrate 110 is exposed for processing. In some embodiments, a carrier 800 is attached to the frontside of the IC device, as shown. The carrier 800 is omitted from view in subsequent figures for simplicity of illustration. The carrier 800 may be attached to a top surface (or “frontside”) of the device by a release layer (not shown). The carrier 80 may comprise glass, ceramic, bulk silicon, or the like while the release layer may include a die attach film (DAF), a dielectric material, or the like. After the carrier 800 is attached, an orientation of the device is flipped (e.g., so that the carrier 800 is disposed below the device), and the substrate 110 is removed.

In FIG. 28, the substrate 110 may be removed, thereby exposing the bottom sides 250U, 254U of the through vias 250, 254. In some embodiments, a planarization process (e.g., CMP, grinding, or the like) may be applied to remove the substrate 110. In some embodiments, the fins 32 are removed in the planarization process. In some embodiments, the planarization process stops on an etch stop layer (omitted from view in the figures) that may be formed prior to the operations shown in FIGS. 2A, 2B. The etch stop layer, when present, may be in contact with bottom surfaces of the isolation regions 36. Following removal of material underlying the etch stop layer, the etch stop layer may be removed by a suitable etching process, such as an isotropic etch that removes material of the etch stop layer without substantially attacking materials of the underlying layers mentioned. The substrate 110 may alternatively be removed by grinding, an etch, or the like.

In some embodiments, following removal of the substrate 110, the fin structures 32 remain in the IC device. In some embodiments, removal of the substrate 110 includes removing the fin structures 32. When the fin structures 32 are removed, a backside dielectric layer may be formed thereafter to isolate (e.g., electrically and physically) subsequently formed conductive features from the gate structures 200.

In some embodiments, remaining height of the fin structures 32 in the Z-axis direction is in a range of about 20 nm to about 35 nm. The remaining height being above 20 nm is advantageous for isolating backside conductive features from the gate structures 200. The remaining height being below 35 nm is advantageous for reducing electrical resistance of the through vias 250, 254.

As shown in the view of FIG. 28, fin structures 32 on either side of the signal via 250 may have portions (e.g., due to jog) that are narrower adjacent the signal via 250, which increases available space for accommodating the signal via 250, and is advantageous to reduce formation of defects in neighboring source/drain regions 82 during etch of the third opening 310C in which the signal via 250 is formed. The narrower portions of the fin structures 32 may have width in the Y-axis direction that is greater than about half that of remaining portions of the fin structures 32.

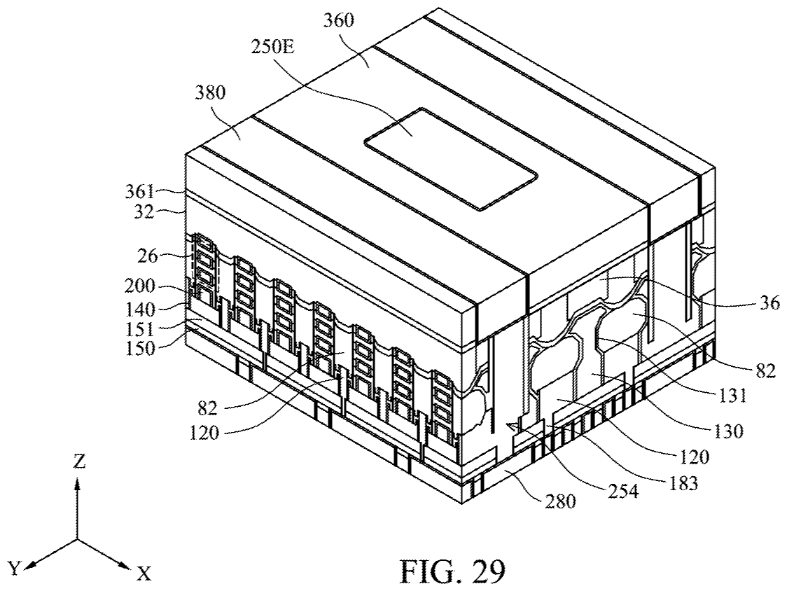

In FIG. 29, following removal of the substrate 110, a backside metallization layer is formed on the backside of the structure of FIG. 28, corresponding to operations 1700 and 1800 of FIG. 32. Operations 1700 and 1800 are performed simultaneously. The backside metallization layer may include a backside ILD 360 and one or more conductive features disposed therein. The conductive features may include a backside power rail 380 (operation 1700) and a backside through via layer 250E (operation 1800). In some embodiments, a backside ESL 361 is formed prior to forming the backside ILD 360, such that the backside ESL 361 is between the backside ILD 360 and the fin structures 32 and the isolation regions 36. The backside power rail 380 and the backside through via layer 250E may be referred to as “backside conductive features.”

The backside ESL 361 and the backside ILD 360 may be formed by one or more deposition operations, such as a PVD, CVD, ALD or the like. Openings may be formed in the backside ILD 360 by one or more photolithography operations, including one or more etching operations that removes exposed portions of the backside ILD 360. The etching operations may terminate on the backside ESL 361, when present, then a subsequent etching operation may be performed to break through the backside ESL 361 and expose the power vias 254 and the signal via 250. The backside power rails 380 may be formed in some of the openings, and the backside through via layer 250E may be formed in another of the openings on the signal via 250. Additional backside metallization layers similar to that shown in FIG. 29 may be formed on the backside metallization layer shown in FIG. 29. For example, the IC device may include two or more (e.g., four, five, six or more) backside metallization layers including that shown in FIG. 29. Following formation of the backside metallization layers, the carrier 800 may be removed.

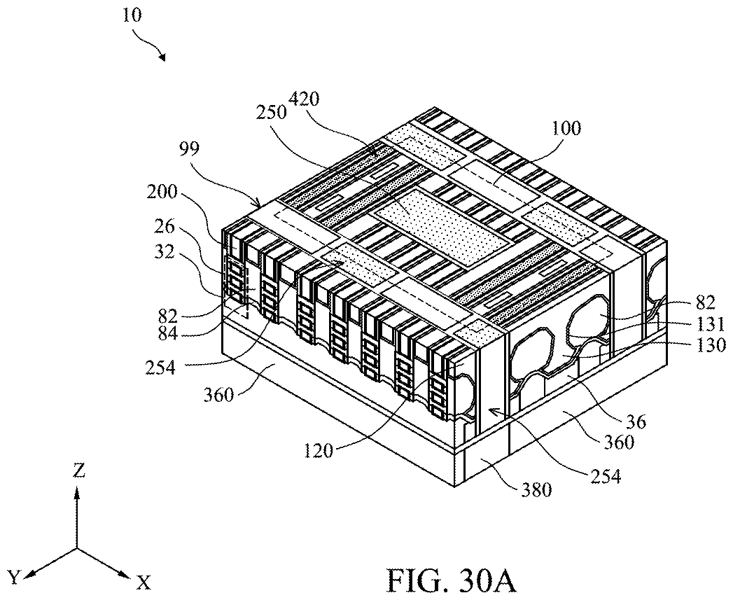

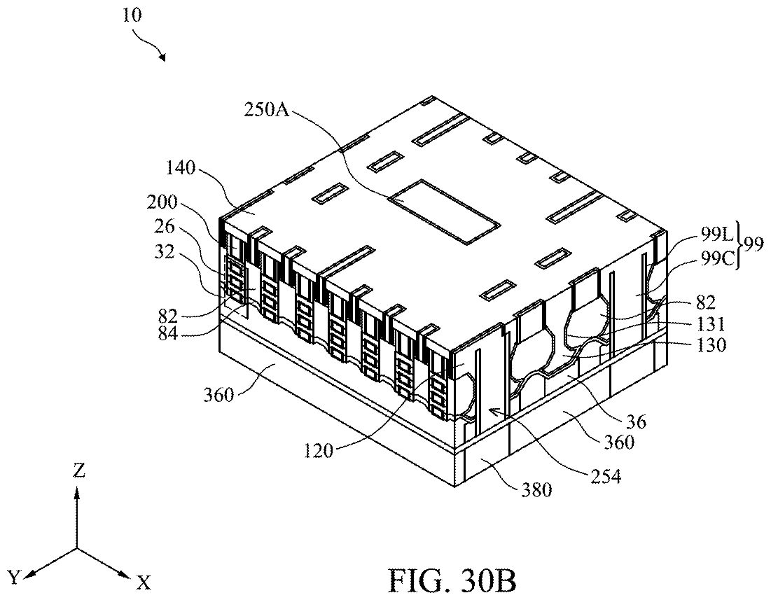

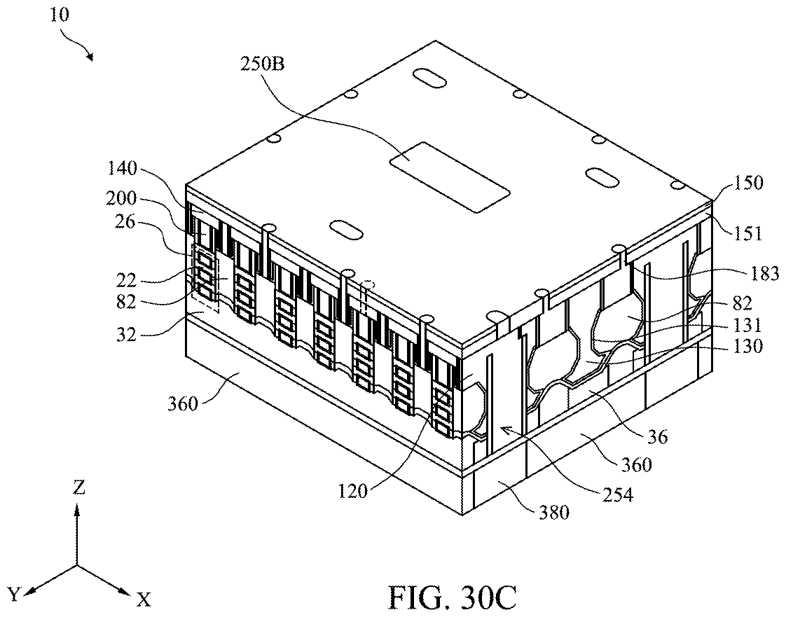

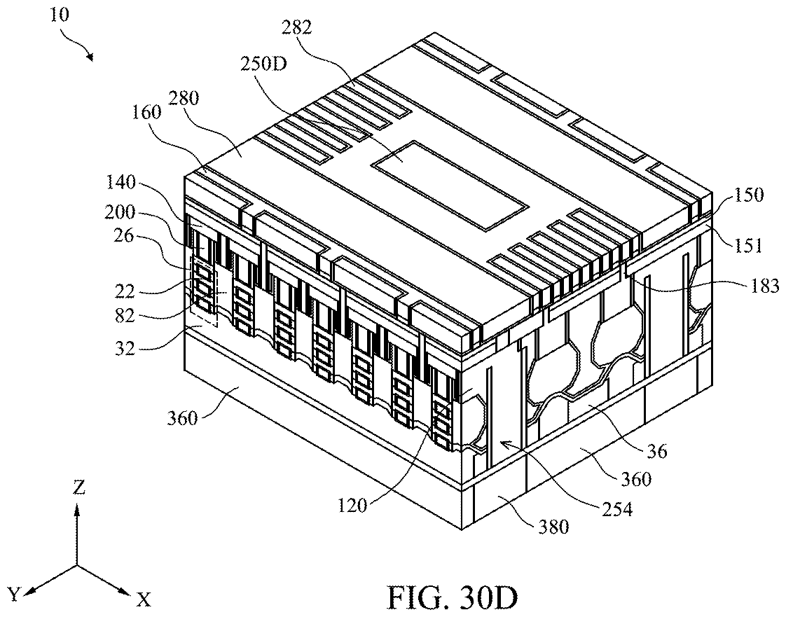

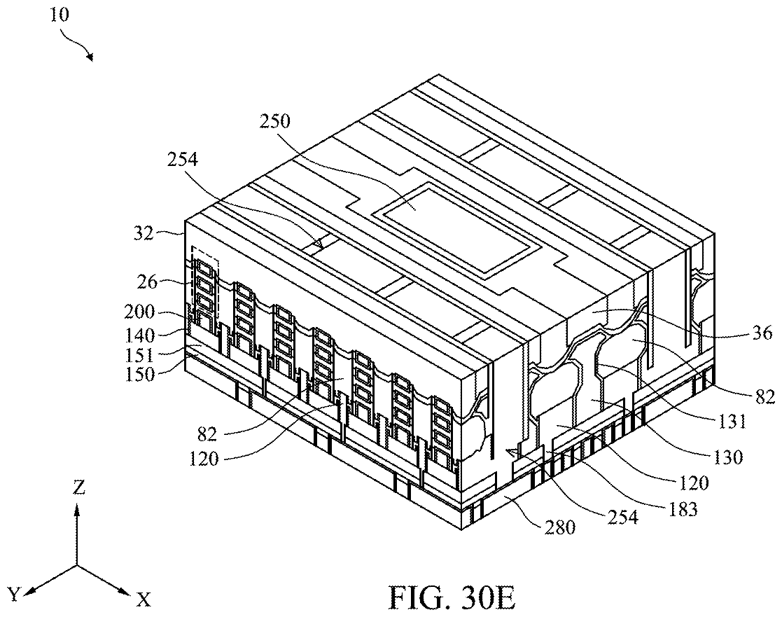

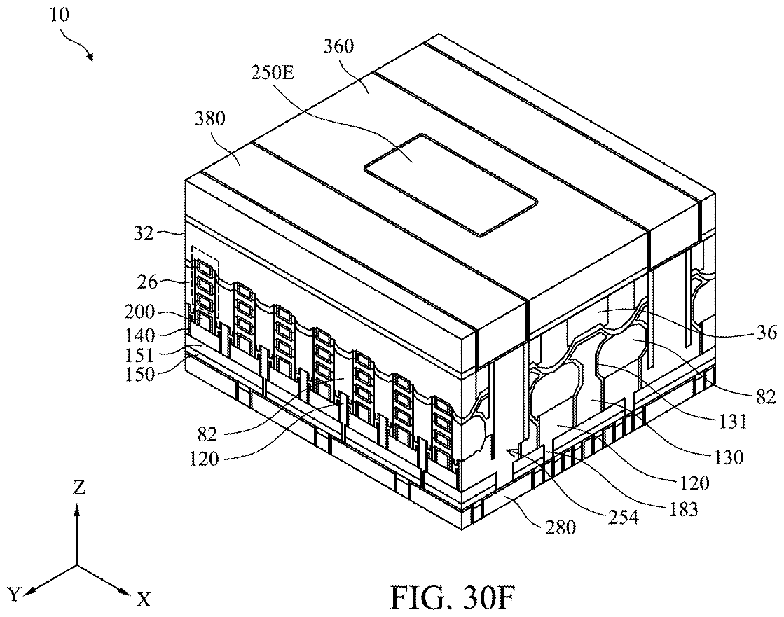

FIGS. 30A-30F are diagrammatic perspective views of various layers of the IC device 10 in accordance with various embodiments. FIG. 30A shows a device layer including front-end-of-line (FEOL) features and with middle-end-of-line (MEOL) and BEOL interconnect structures omitted from view. FIG. 30A shows an IC cell 100 that is bordered by the power vias 254 and the CPODEs 420, and includes six transistors with the signal via 250 therebetween. FIG. 30B shows a first MEOL layer on the device layer. FIG. 30C shows a second MEOL layer on the first MEOL layer. FIG. 30D shows a first BEOL layer on the second MEOL layer. FIG. 30E shows the device layer with the backside thereof facing up. FIG. 30F shows a first backside BEOL layer on the device layer.

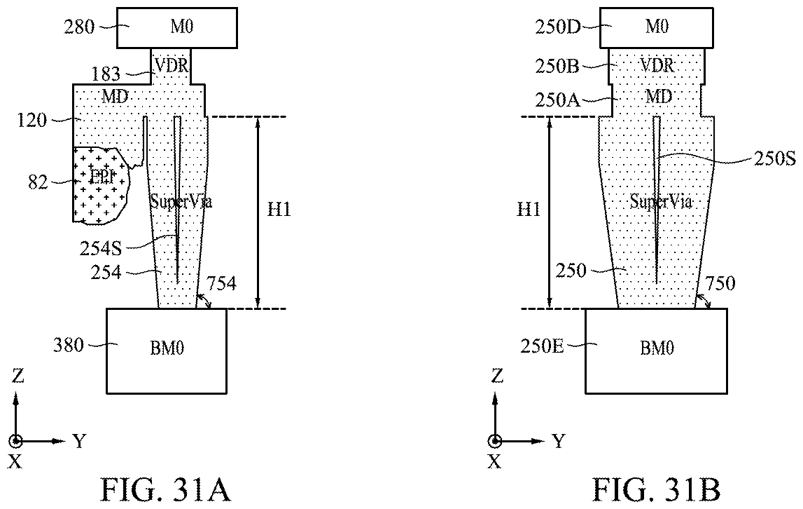

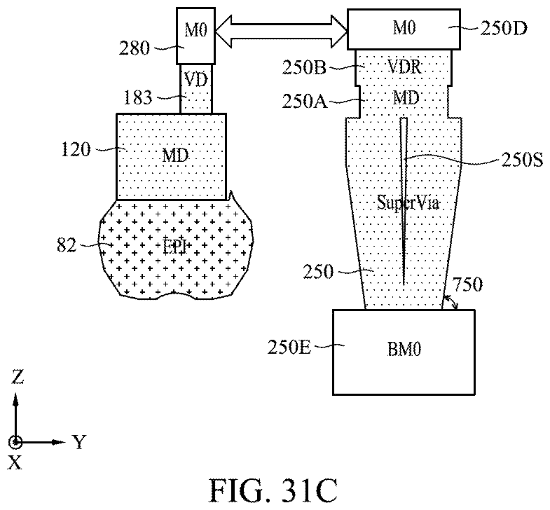

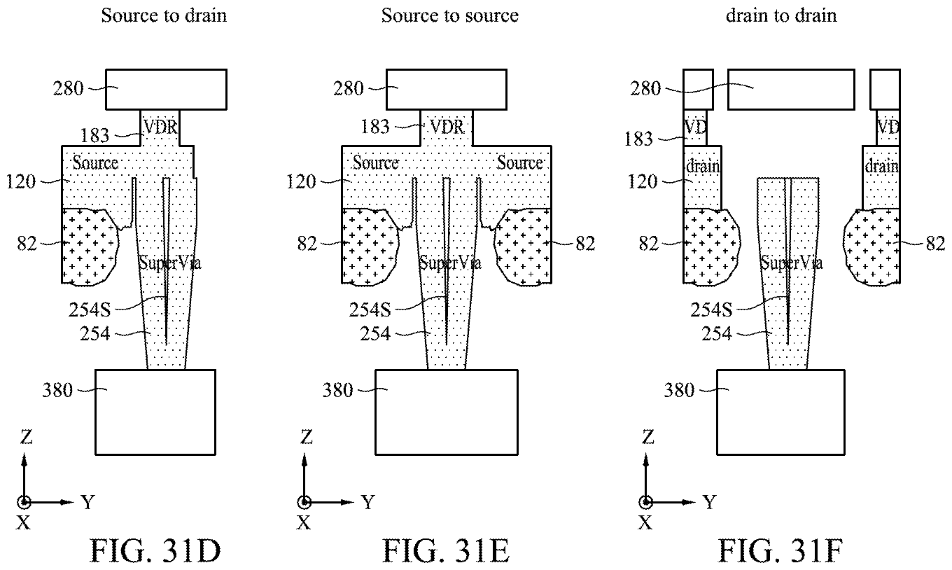

FIGS. 31A-31F are diagrammatic cross-sectional side views of the through vias 250, 254 in accordance with various embodiments.

FIG. 31A shows the power via 254 in accordance with various embodiments. FIG. 31B shows the signal via 250 in accordance with various embodiments. As can be seen in FIGS. 31A, 31B, each of the power via 254 and the signal via 250 is part of a respective stack that includes the frontside power line 280 or the third through via layer 250C in the first BEOL layer (“MO”), the expanded source/drain vias 183, 250B in the second MEOL layer (“VDR”), the source/drain contact 120 or the second through via layer 250A in the first MEOL layer (“MD”), the power via 254 or the signal via 250 in the device layer (“SuperVia”), and the backside power rail 380 or the backside through via layer 250E in the first backside BEOL layer (“BM0”). As such, the power via 254 and the signal via 250 may be formed in the same manufacturing processes, without using complicated processes to form the power via 254 and the signal via 250 separately.

Dimension or height H1 is shown in FIGS. 31A, 31B, and is height of the through vias 250, 254, which may be in a range of about 60 nm to about 180 nm. The heights H1 of the through vias 250, 254 may be the same as each other due to frontside CMP and backside wafer thinning, as described with reference to FIGS. 22A, 22B and FIG. 28.

FIGS. 31A, 31B illustrate seams 250S, 254S in the through vias 250, 254. In some embodiments, the seams or voids 250S, 254S have width in a range of about 1 nm to about 5 nm. In some embodiments, the seams or voids 250S, 254S are not present, for example, when a bottom-up metal growth process is performed to form the through vias 250, 254.

The through vias 250, 254 may be formed having tapered sidewalls, as shown in FIGS. 31A, 31B. The through vias 254 may be formed having a taper angle 754 in a range of about 85 degrees to about 90 degrees. The through via 250 may be formed having a taper angle 750 in a range of about 85 degrees to about 90 degrees. In some embodiments, the taper angle 750 is different than the taper angle 754. For example, the taper angle 750 may be larger than the taper angle 754, for example, due to aspect ratio of the signal via 250 being less than aspect ratio of the power via 254.

In some embodiments, the through vias 250, 254 have inverted tapered profile, for example, in the Y-Z plane. In the above description of FIGS. 2A-29, openings for forming the through vias 250, 254 are etched from the frontside of the IC device 10, such that the through vias 250, 254 have tapered profile in the Y-Z plane that becomes gradually narrower with increased proximity to a backside conductive feature 380. In some embodiments, the openings for forming the through vias 250, 254 may be etched from the backside of the IC device 10, such that the through vias 250, 254 have profile in the Y-Z plane that becomes gradually wider with increased proximity to the backside conductive feature 380. For example, the openings 310B, 310C may be filled with one or more dielectric plugs prior to forming the source/drain contacts 120, source/drain vias 183 and frontside power rails 280. Then, in backside processing, thinning the substrate 110 may expose the dielectric plugs. The dielectric plugs may then be removed to reopen the openings 310B, 310C, and the through vias 250, 254 may be formed in the reopened openings 310B, 310C. In such embodiments, when the openings 310B, 310C are reopened by a suitable etching process, the openings 310B, 310C may have profile that narrows with proximity to the source/drain contacts 120 and/or the first through via layer 250A. The through vias 250, 254 may adopt the shape and profile of the openings 310B, 310C, and may have profile that narrows toward the source/drain contacts 120 and/or first through via layer 250A.

FIG. 31C shows a source/drain region 82 that may be in electrical communication with the signal via 250. In some embodiments, a source/drain contact 120 is on the source/drain region 82, a source/drain via 183 is on the source/drain contact 120, and a frontside trace 280 is on the source/drain via 183. The frontside trace 280 is in the same metal layer as the third through via layer 250C, which is electrically connected to the signal via 250 through the first and second through via layers 250A, 250B. In some embodiments, the frontside trace 280 is in contact with the third through via layer 250C. In some embodiments, the frontside trace 280 may be in electrical contact with the third through via layer 250C via one or more conductive features in a metal layer that is above the frontside trace 280 and the third through via layer 250C.

FIGS. 31D-31F show structural relationships between conductive features in the first MEOL layer MD and the through via 250 or the through via 254. Description is given in terms of the power via 254, but may be similarly applicable to the signal via 250. FIG. 31D shows a source-to-drain structure, in which a source region 82 is coupled to the through via 254 by a source/drain contact 120 that is in contact with the source region 82 and the through via 254. FIG. 31E shows a source-to-source structure, in which a first source region 82 is coupled to the through via 254 and a second source region 82 by source/drain contacts 120. FIG. 31F shows a drain-to-drain structure, in which a first drain 82 and a second drain 82 are physically and electrically isolated from the through via 254. For example, drain contacts 120 overlying the first and second drains 82 are isolated from the through via 254. It should be understood that, FIGS. 31D-31F show embodiments associated with possible cases in circuit layouts. FIG. 31D shows that only one side of a cell (e.g., a source side) has a demand for power while the other side does not. FIG. 31E shows that both sides have such demand. FIG. 31F shows that some cells have no power demand in the YZ-plane view, and, for example, may have power demand on other YZ-plane regions not illustrated herein.

Embodiments may provide advantages. The through vias 250, 254 provide frontside signal and power routing flexibility by enabling signal and power wires to be disposed on the backside of the device 10. Forming the power wires on the back side of the device 10 allows for wider power wires, which reduces resistance and increases power efficiency. The through vias 250, 254 may be formed from the frontside of the device or the backside of the device. Use of the through vias 250, 254 may reduce resistance and increase speed, while also simplifying routing of power and signal wires.

In accordance with at least one embodiment, a device includes: a stack of semiconductor nanostructures; a gate structure wrapping around the semiconductor nanostructures, the gate structure extending in a first direction; a source/drain region abutting the gate structure and the stack in a second direction transverse the first direction; a contact structure on the source/drain region; a backside conductive trace under the stack, the backside conductive trace extending in the second direction; a first through via that extends vertically from the contact structure to a top surface of the backside dielectric layer; and a gate isolation structure that abuts the first through via in the second direction.

In accordance with at least one embodiment, a method includes: forming a vertical stack of nanostructure channels over a substrate; forming a source/drain region abutting the nanostructure channels; forming a gate structure that wraps around the nanostructure channels and extends past the nanostructure channels in a first direction; forming a first opening that extends through the gate structure; forming a gate isolation structure in the first opening; forming a second opening adjacent the gate isolation structure in the second direction; forming a first through via in the second opening; forming a contact structure in contact with the first via structure and the source/drain region; and forming a backside conductive trace in contact with the first through via.

In accordance with at least one embodiment, a method includes: forming a vertical stack of nanostructure channels over a substrate; forming a source/drain region abutting the nanostructure channels; forming a gate structure wrapping around the nanostructure channels; forming a first through via adjacent the gate structure, and a second through via adjacent the gate structure, the first through via and the second through via being on opposite sides of the gate structure; forming a contact structure having an underside in contact with the source/drain region and the first through via; and forming respective backside conductive features in contact with the first through via and the second through via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a stack of semiconductor nanostructures;
a gate structure wrapping around the semiconductor nanostructures, the gate structure extending in a first direction;
a source/drain region abutting the gate structure and the stack in a second direction transverse the first direction;
a contact structure on the source/drain region;
a backside conductive trace under the stack, the backside conductive trace extending in the second direction;
a first through via that extends vertically from the contact structure to a top surface of the backside dielectric layer; and
a gate isolation structure that abuts the first through via in the second direction.

2. The device of claim 1, further comprising:
a second through via offset from the first through via in the first direction;
a second gate isolation structure that abuts the second through via in the second direction.

3. The device of claim 2, further comprising:
a third through via between the first through via and the second through via in the first direction.

4. The device of claim 3, further comprising:
a first isolation structure that extends in the first direction; and
a second isolation structure that extends in the first direction and is offset from the first isolation structure along the second direction;
wherein the third through via is between the first isolation structure and the second isolation structure.

5. The device of claim 1, further comprising:
a second source/drain region on an opposite side of the first through via than the source/drain region; and
a second contact structure that is in contact with the second source/drain region and the first through via.

6. The device of claim 1, wherein the through via has a tapered profile that narrows with increased proximity to the backside conductive trace.

7. The device of claim 1, wherein the through via has width that increases with increased proximity to the backside dielectric layer.

8. A method, comprising:
forming a vertical stack of nanostructure channels over a substrate;
forming a source/drain region abutting the nanostructure channels;
forming a gate structure that wraps around the nanostructure channels and extends past the nanostructure channels in a first direction;
forming a first opening that extends through the gate structure;
forming a gate isolation structure in the first opening;
forming a second opening adjacent the gate isolation structure in the second direction;
forming a first through via in the second opening;
forming a contact structure in contact with the first via structure and the source/drain region; and
forming a backside conductive trace in contact with the first through via.

9. The method of claim 8, further comprising:
forming a second through via offset from the first through via in the first direction; and
forming a second backside conductive trace in contact with the second through via.

10. The method of claim 9, wherein the first through via and the second through via are formed simultaneously in a first process.

11. The method of claim 10, wherein the first process includes:
depositing a conductive material in the second opening and in a third opening offset from the second opening in the first direction.

12. The method of claim 11, wherein the first process includes:
forming a dielectric liner layer in the second and third openings prior to the depositing a conductive material.

13. The method of claim 8, further comprising:
forming a second source/drain region during the forming a source/drain region; and
forming a second contact structure in contact with the first via structure and the second source/drain region;
wherein the second source/drain region is on an opposite side of the first via structure from the source/drain region.

14. A method, comprising:
forming a vertical stack of nanostructure channels over a substrate;
forming a source/drain region abutting the nanostructure channels;
forming a gate structure wrapping around the nanostructure channels;
forming a first through via adjacent the gate structure, and a second through via adjacent the gate structure, the first through via and the second through via being on opposite sides of the gate structure;
forming a contact structure having an underside in contact with the source/drain region and the first through via; and
forming respective backside conductive features in contact with the first through via and the second through via.

15. The method of claim 14, further comprising:
exposing the first and second through vias by removing the substrate;
forming a backside dielectric layer in contact with the first and second through vias; and
exposing the first and second through vias by forming a first opening and a second opening in the backside dielectric layer;
wherein the forming respective backside conductive features includes depositing a conductive material in the first opening and the second opening.

16. The method of claim 15, wherein the first and second through vias have the same height.

17. The method of claim 15, further comprising:
forming a source/drain via on the contact structure; and
forming a frontside conductive feature on the first through via.

18. The method of claim 15, wherein removing the substrate removes a fin structure underlying the vertical stack of nanostructure channels.

19. The method of claim 14, further comprising:
forming a bottom isolation layer on a fin structure underlying the nanostructure channels;
wherein the forming a source/drain region includes epitaxially growing the source/drain region on the nanostructure channels, and the source/drain region is isolated from the fin structure by the bottom isolation layer.

20. The method of claim 19, further comprising:
exposing the first and second through vias and the fin structure by removing the substrate;
wherein height of the fin structure is in a range of about 20 nanometers to about 35 nanometers following removal of the substrate.
